(19) United States
(12) Patent Application Publication
(10) Pub. No.: US 2015/0303377 A1
(43) Pub. Date: Oct. 22, 2015

(54) COMPOUNDS CAPABLE OF UNDERGOING SYMMETRY BREAKING INTRAMOLECULAR CHARGE TRANSFER IN A POLARIZING MEDIUM AND ORGANIC PHOTOVOLTAIC DEVICES COMPRISING THE SAME

(71) Applicants: Mark E. Thompson, Anaheim, CA (US); Matthew T. Whited, Northfield, MN (US); Niral M. Patel, Midland, MI (US); Peter I. Djurovich, Long Beach, CA (US); Stephen R. Forrest, Ann Arbor, MI (US); Kathryn R. Allen, Los Angeles, CA (US); Cong Trinh, Los Angeles, CA (US)

(72) Inventors: Mark E. Thompson, Anaheim, CA (US); Matthew T. Whited, Northfield, MN (US); Niral M. Patel, Midland, MI (US); Peter I. Djurovich, Long Beach, CA (US); Stephen R. Forrest, Ann Arbor, MI (US); Kathryn R. Allen, Los Angeles, CA (US); Cong Trinh, Los Angeles, CA (US)

(21) Appl. No.: 13/564,953

(22) Filed: Aug. 2, 2012

Related U.S. Application Data
(60) Provisional application No. 61/514,079, filed on Aug. 2, 2011.

(51) Int. Cl. H01L 51/00; C07F 3/06; C07F 5/02

(52) U.S. Cl. CPC H01L 51/008; C07F 5/022; C07F 3/06; H01L 51/0092; H01L 51/44

(57) ABSTRACT

The present disclosure generally relates to chromophoric compounds that combine strong absorption of light at visible wavelengths with the ability to undergo symmetry-breaking intramolecular charge transfer (ICT), and their use for the generation of free carriers in organic photovoltaic cells (OPVs) and electric-field-stabilized geminate polaron pairs. The present disclosure also relates to the synthesis of such compounds, methods of manufacture, and applications in photovoltaic systems and organic lasers.

### CROSS-REFERENCE TO RELATED APPLICATION

This application claims the benefit of priority to U.S. Provisional Application No. 61/514,079, filed on Aug. 2, 2011, which is incorporated herein by reference in its entirety.

### STATEMENT REGARDING FEDERALLY SPONSORED RESEARCH

This invention was made with U.S. Government support under Contract No. DE-SC0001013 awarded by the Department of Energy. The government has certain rights to this invention.

### JOINT RESEARCH AGREEMENT

The claimed invention was made by, on behalf of, and/or in connection with one or more of the following parties to a joint university-corporation research agreement: University of Southern California, University of Michigan, and Global Photonic Energy Corporation. The agreement was in effect on and before the date the invention was made, and the claimed invention was made as a result of activities undertaken within the scope of the agreement.

The present disclosure generally relates to chromophoric compounds that combine strong absorption of light at visible to near infrared wavelengths with the ability to undergo symmetry-breaking intramolecular charge transfer (ICT), and their use for the generation of free carriers in organic photovoltaic cells (OPVs) and electric-field-stabilized geminate polaron pairs. The present disclosure also relates to the synthesis of such compounds, methods of manufacture, and applications in photovoltaic systems and organic lasers.

Optoelectronic devices rely on the optical and electronic properties of materials to either produce or detect electromagnetic radiation electronically, or to generate electricity from ambient electromagnetic radiation.

Photosensitive optoelectronic devices convert electromagnetic radiation into electricity. Solar cells, also called photovoltaic (PV) devices, are a type of photosensitive optoelectronic device that is specifically used to generate electrical power. PV devices, which may generate electrical energy from light sources other than sunlight, can be used to drive power consuming loads to provide, for example, lighting, heating, or to power electronic circuitry or devices such as calculators, radios, computers or remote monitoring or communications equipment. These power generation applications also often involve the charging of batteries or other energy storage devices so that operation may continue when direct illumination from the sun or other light sources is not available, or to balance the power output of the PV device with a specific application's requirements. As used herein the term “resistive load” refers to any power consuming or storing circuit, device, equipment or system.

Another type of photosensitive optoelectronic device is a photoconductor cell. In this function, signal detection circuitry monitors the resistance of the device to detect changes due to the absorption of light.

Another type of photosensitive optoelectronic device is a photodetector. In operation a photodetector is used in conjunction with a current detecting circuit which measures the current generated when the photodetector is exposed to electromagnetic radiation and may have an applied bias voltage. A detecting circuit as described herein is capable of providing a bias voltage to a photodetector and measuring the electronic response of the photodetector to electromagnetic radiation.

These three classes of photosensitive optoelectronic devices may be characterized according to whether a rectifying junction as defined below is present, and also according to whether the device is operated with an external applied voltage, also known as a bias or bias voltage. A photoconductor cell does not have a rectifying junction and is normally operated with a bias. A PV device has at least one rectifying junction and is operated with no bias. A photodetector has at least one rectifying junction and is usually but not always operated with a bias. As a general rule, a photovoltaic cell provides power to a circuit, device or equipment, but does not provide a signal or current to control detection circuitry, or the output of information from the detection circuitry. In contrast, a photodetector or photoconductor provides a signal or current to control detection circuitry, or the output of information from the detection circuitry but does not provide power to the circuitry, device or equipment.

Traditionally, photosensitive optoelectronic devices have been constructed of a number of inorganic semiconductors, e.g., crystalline, polycrystalline and amorphous silicon, gallium arsenide, cadmium telluride and others. Herein the term “semiconductor” denotes materials which can conduct electricity when charge carriers are induced by thermal or electromagnetic excitation. The term “photoconductive” generally relates to the process in which electromagnetic radiant energy is absorbed and thereby converted to excitation energy of electric charge carriers so that the carriers can conduct, i.e., transport, electric charge in a material. The terms “photoconductor” and “photoconductive material” are used herein to refer to semiconductor materials which are chosen for their property of absorbing electromagnetic radiation to generate electric charge carriers.

PV devices may be characterized by the efficiency with which they can convert incident solar power to useful electric power. Devices utilizing crystalline or amorphous silicon dominate commercial applications, and some have achieved efficiencies of 23% or greater. However, efficient crystalline-based devices, especially of large surface area, are difficult and expensive to produce due to the problems inherent in producing large crystals without significant efficiency-degrading defects. On the other hand, high efficiency amorphous silicon devices still suffer from problems with stability. Present commercially available amorphous silicon cells have stabilized efficiencies between 4 and 8%.

PV devices may be optimized for maximum electrical power generation under standard illumination conditions (i.e., Standard Test Conditions which are 1000 W/m², AM1.5 spectral illumination), for the maximum product of photocurrent times photovoltage. The power conversion efficiency of such a cell under standard illumination conditions depends on the following three parameters: (1) the current under zero bias, i.e., the short-circuit current I_{SC}, in Amperes; (2) the photovoltage under open circuit conditions, i.e., the open circuit voltage V_{OC}, in Volts; and (3) the fill factor, ff.

PV devices produce a photo-generated current when they are connected across a load and are irradiated by light. When irradiated under infinite load, a PV device generates its maximum possible voltage, V open-circuit, or V_{OC}. When irradiated with its electrical contacts shorted, a PV device generates its maximum possible current, I short-circuit, or I_{SC}. When actually used to generate power, a PV device is connected to a finite resistive load and the power output is given by the product of the current and voltage, I×V. The maximum total power generated by a PV device is inherently incapable of exceeding the product I_{SC}×V_{OC}. When the load value is optimized for maximum power extraction, the current and voltage have the values Iₘₐₓ and Vₘₐₓ, respectively.

A figure of merit for PV devices is the fill factor, ff, defined as:

ff={IₘₐₓVₘₐₓ}/{I_{SC}V_{OC}} (1)

where ff is always less than 1, as I_{SC} and V_{OC} are never obtained simultaneously in actual use. Nonetheless, as ff approaches 1, the device has less series or internal resistance and thus delivers a greater percentage of the product of I_{SC} and V_{OC} to the load under optimal conditions. Where P_{inc} is the power incident on a device, the power efficiency of the device, η_{P}, may be calculated by:

η_{P}=ff*(I_{SC}*V_{OC})/P_{inc}

To produce internally generated electric fields that occupy a substantial volume of the semiconductor, the usual method is to juxtapose two layers of material with appropriately selected conductive properties, especially with respect to their distribution of molecular quantum energy states. The interface of these two materials is called a photovoltaic junction. In traditional semiconductor theory, materials for forming PV junctions have been denoted as generally being of either n- or p-type. Here n-type denotes that the majority carrier type is the electron. This could be viewed as the material having many electrons in relatively free energy states. The p-type denotes that the majority carrier type is the hole. Such material has many holes in relatively free energy states. The type of the background, i.e., not photo-generated, majority carrier concentration depends primarily on unintentional doping by defects or impurities. The type and concentration of impurities determine the value of the Fermi energy, or level, within the gap between the conduction band minimum and valance band maximum energies. The Fermi energy characterizes the statistical occupation of molecular quantum energy states denoted by the value of energy for which the probability of occupation is equal to %. A Fermi energy near the conduction band minimum energy indicates that electrons are the predominant carrier. A Fermi energy near the valence band maximum energy indicates that holes are the predominant carrier. Accordingly, the Fermi energy is a primary characterizing property of traditional semiconductors and the prototypical PV junction has traditionally been the p-n interface.

The term “rectifying” denotes, inter alia, that an interface has an asymmetric conduction characteristic, i.e., the interface supports electronic charge transport preferably in one direction. Rectification is associated normally with a built-in electric field which occurs at the junction between appropriately selected materials.

Photoinduced electron transfer reactions are important for energy storage processes in both biological and photovoltaic systems. Interfacial charge separation is a crucial step in the generation of free carriers in OPVs. In the photosynthetic reaction center, electron transfer from the “special pair” is preceded by ultrafast formation of an intradimer charge-transfer state via symmetry breaking. In principle, the same sort of symmetry-breaking strategy could be used to facilitate the generation of free carriers in OPVs, but has not been utilized due to several important limitations. First, in order to form an intramolecular charge-transfer (ICT) state akin to the intradimer Charge Transfer (CT) state in Photosystem II, there must be a driving force for the formation of a CT state. Second, candidate molecules must combine strong absorption of light at visible wavelengths with an ability to undergo symmetry-breaking ICT. There are few dimeric molecules that meet these criteria. To date, the best studied system of this sort is 9,9′-bianthryl. However, 9,9′-bianthryl predominantly absorbs ultraviolet light.

As previously described in the literature, involvement of symmetry-breaking CT states can facilitate charge separation with minimal energy loss and slow recombination. This is likely the reason why the photosynthetic reaction center initiates its electron-transfer cascade with the fast (picosecond) formation of an intradimer CT state. Thus, a minimal-energy-loss mechanism could be useful for maximizing open-circuit voltage in OPVs. However, due to the low diffusivity of CT excitons in neat films, the use of standard donor/acceptor compounds in thin film photovoltaics has proven to be less desirable.

Therefore, there is a present need to develop compounds having accessible symmetry-breaking ICT states, since such states generally only form in polarizing environments. The archetypical example of such a molecule is 9,9′-bianthryl, which forms a normal singlet excited state (S₁) in nonpolar solvents but undergoes ultrafast solvent-induced ICT in more polar environments.

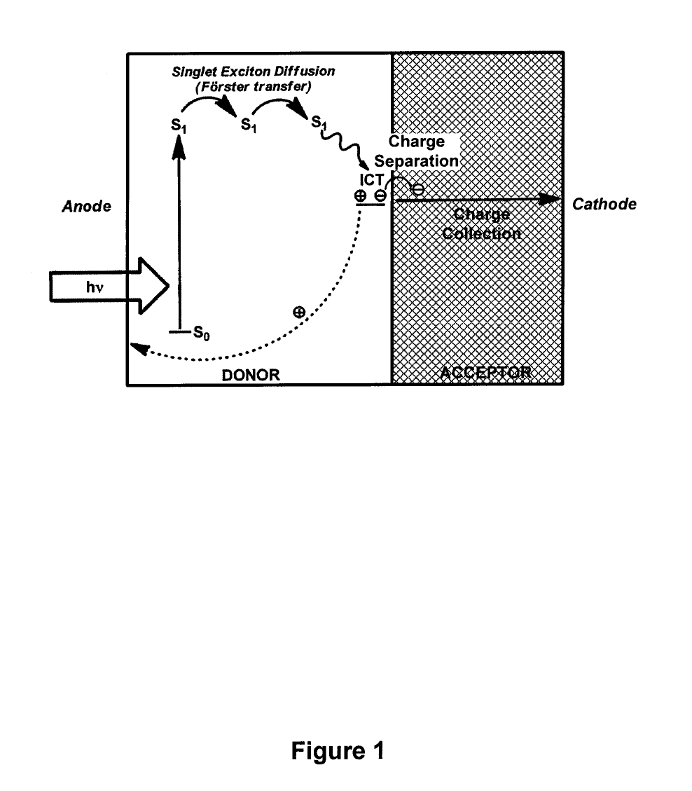

Without wishing to be bound by theory, it is believed that molecules that undergo symmetry-breaking ICT in polar environments will allow excitation energy to move quickly and over long distances through the bulk material in neat films by Forster energy transfer processes before internal conversion to an ICT state by symmetry breaking at the polarizing donor/acceptor interface (FIG. 1).

There is disclosed an organic photosensitive optoelectronic device comprising at least one higher order compound, such as dyads, triads and tetrads, that are capable of undergoing symmetry-breaking intramolecular charge transfer in a polarizing medium. In one embodiment, the intramolecular charge transfer occurs at a polarizing donor/acceptor interface.

The compounds disclosed herein exhibit a high absorptivity of light in the visible and near infrared spectrum. In at least one embodiment, “high absorptivity of light” includes absorptivity of >10⁴ M⁻¹ cm⁻¹ at one or more visible to near infrared wavelengths ranging from 350 to 1500 nm.

In one embodiment, the higher order compound forms at least one donor and/or acceptor region in a donor-acceptor heterojunction. In one embodiment, the donor-acceptor heterojunction absorbs photons to form excitons.

In one embodiment, the device is an organic device, such as an organic photodetector, an organic solar cell, or an organic laser.

There are also disclosed methods of making an organic photosensitive optoelectronic device comprising a higher order compound. In one embodiment, the device may be an organic photodetector, in another an organic solar cell.

The foregoing and other features of the present disclosure will be more readily apparent from the following detailed description of exemplary embodiments, taken in conjunction with the attached drawings. It will be noted that for convenience all illustrations of devices show the height dimension exaggerated in relation to the width.

FIG. 1 is a schematic representation of symmetry-breaking ICT to facilitate charge separation at a polarizing donor/acceptor interface.

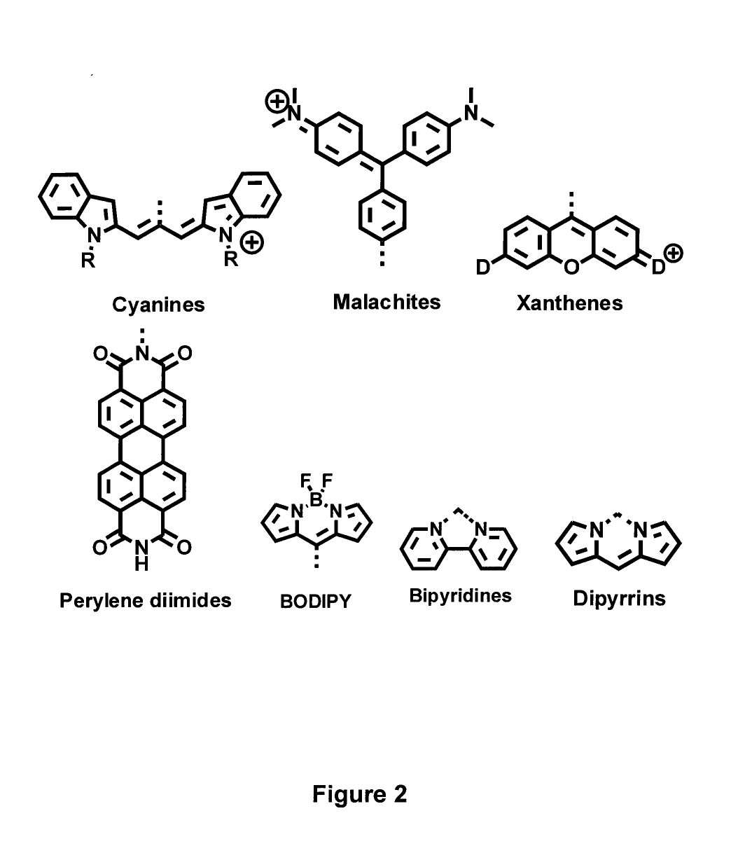

FIG. 2 shows examples of dyes that can be coupled into dimers, trimers, etc. for symmetry breaking ICT.

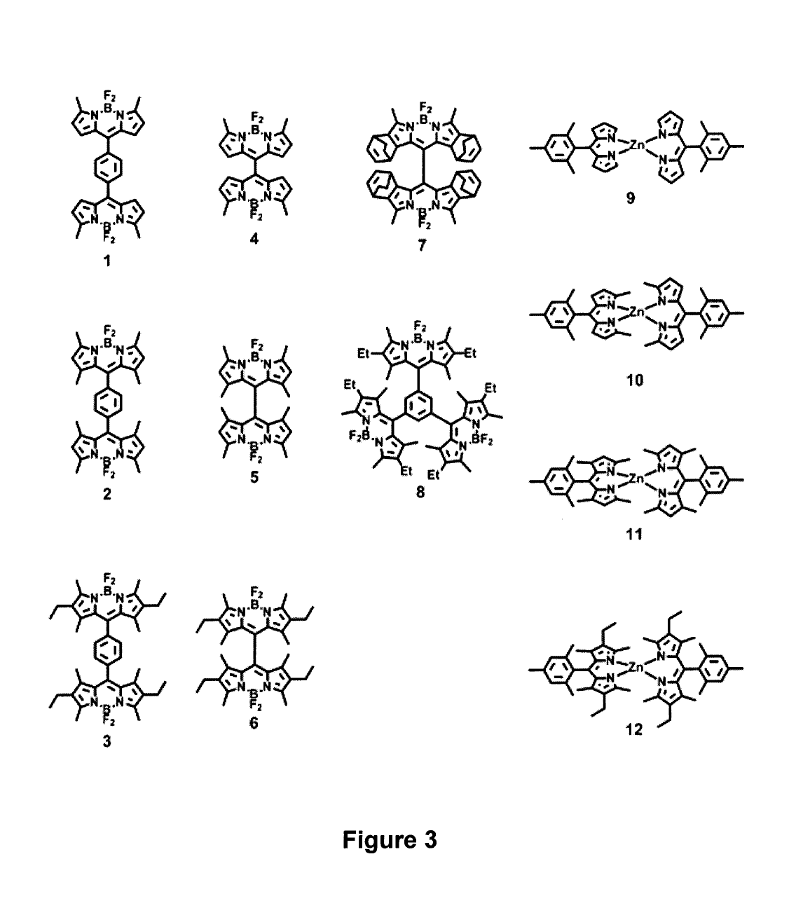

FIG. 3 shows examples of dipyrrin chromophores synthesized for symmetry breaking ICT.

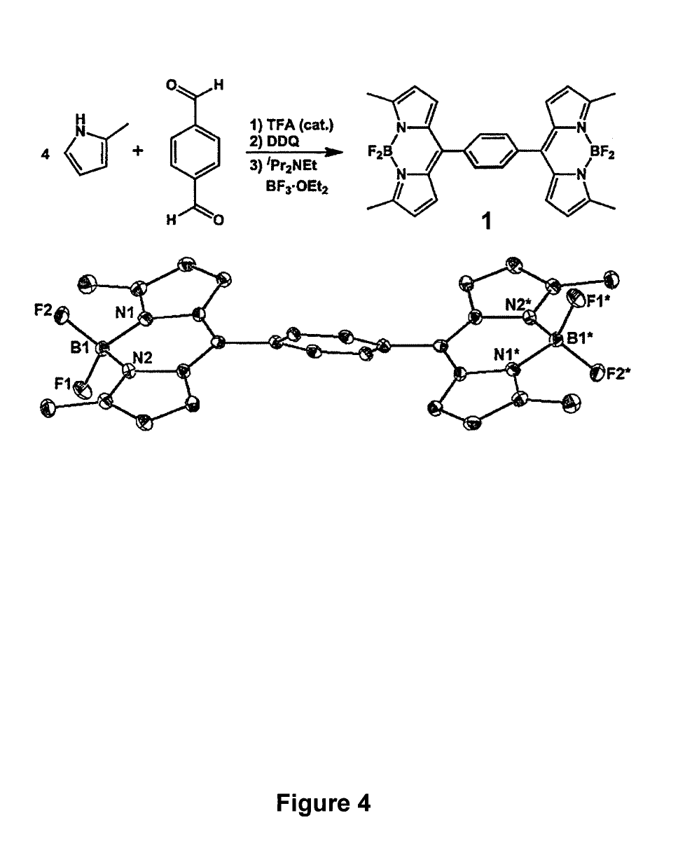

FIG. 4 shows the synthetic scheme and displacement ellipsoid of BODIPY dyad 1 of FIG. 3.

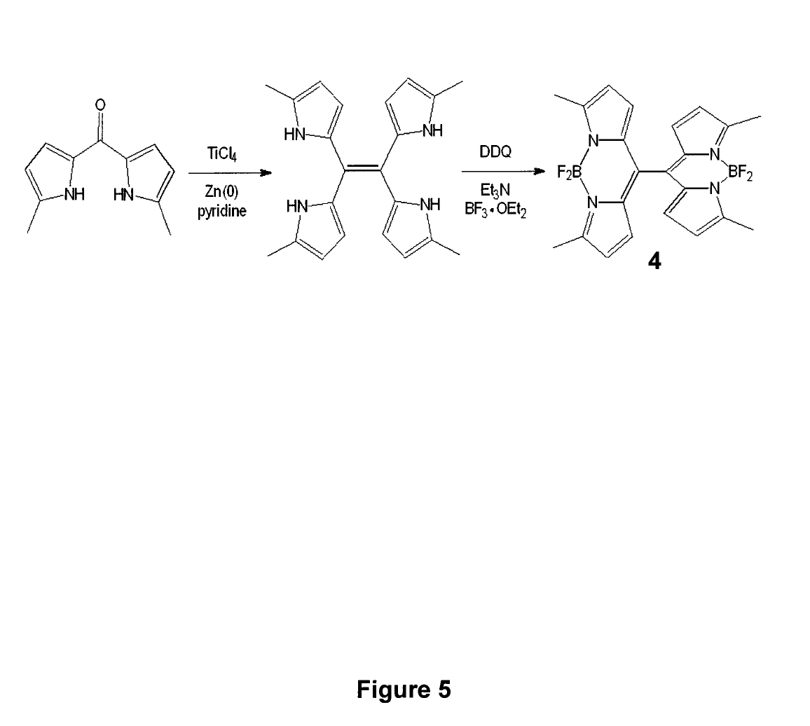

FIG. 5 shows a synthetic scheme of BODIPY dyad 4.

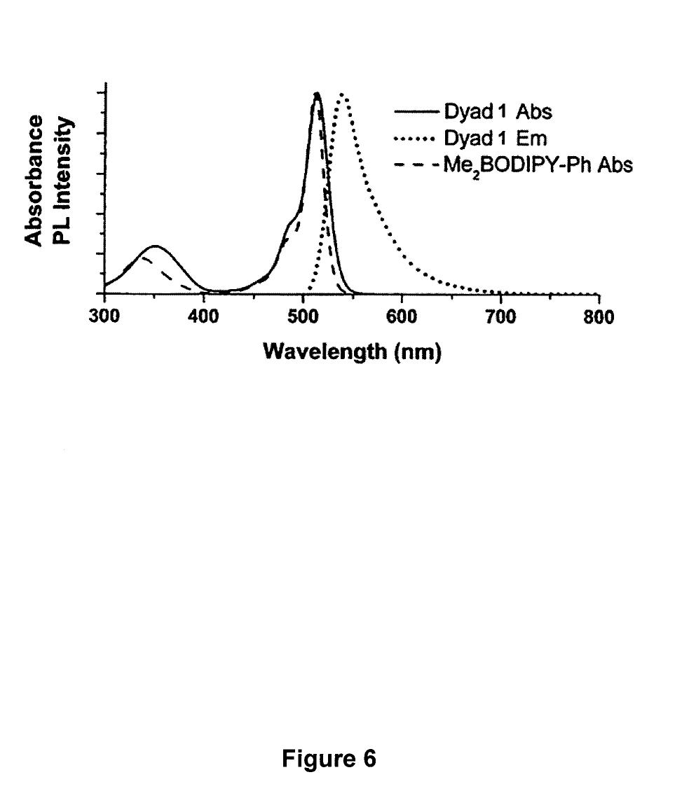

FIG. 6 represents the normalized absorption and emission spectra of dyad 1 and the absorption spectra of 3,5-Me₂BODIPY-Ph in CH₂Cl₂.

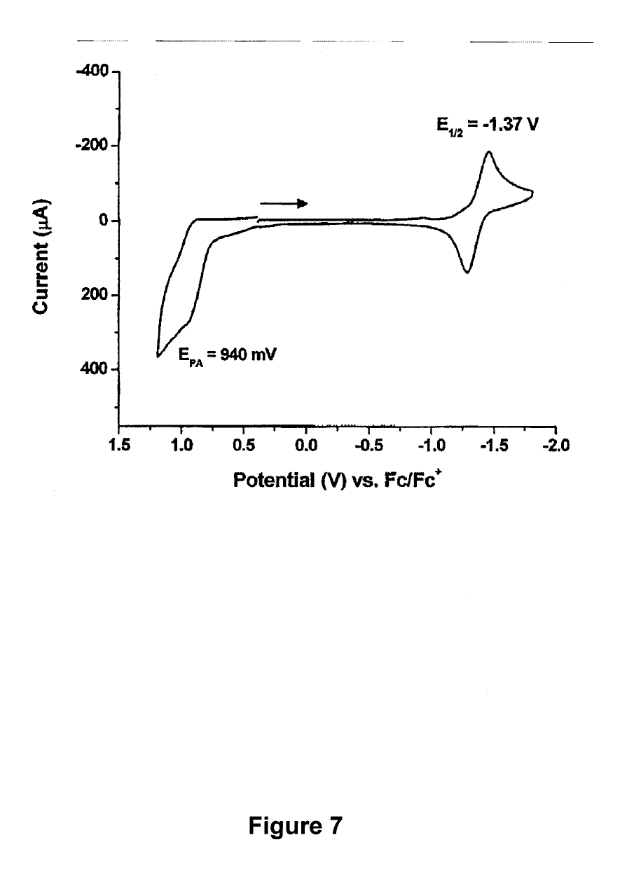

FIG. 7 shows the cyclic voltammetry of dyad 1 in CH₂Cl₂.

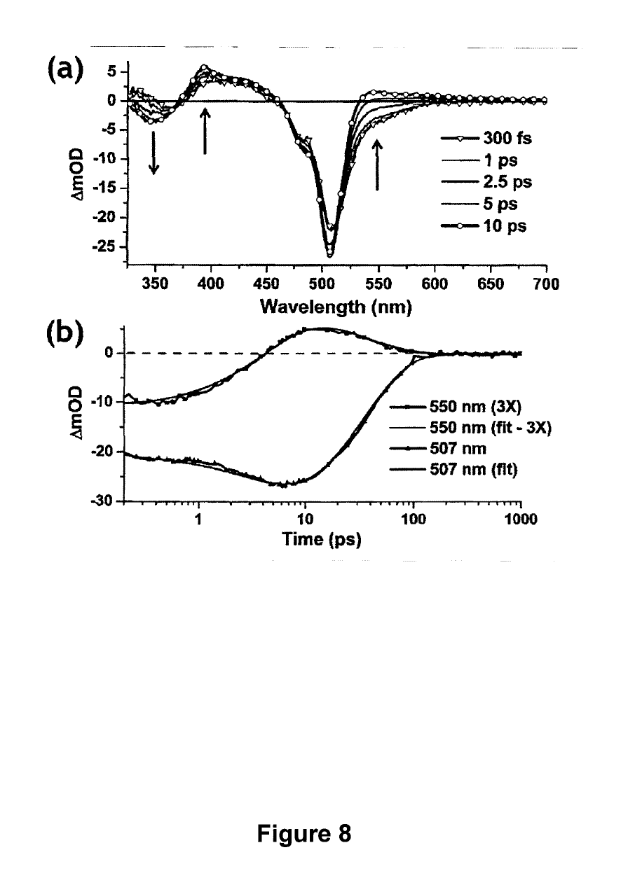

FIGS. 8(a) and (b) represent the ultrafast transient absorption spectra of dyad 1 after excitation at 508 nm, and time domain slices of transient absorptions at 507 and 550 nm with predicted traces based on kinetic parameters.

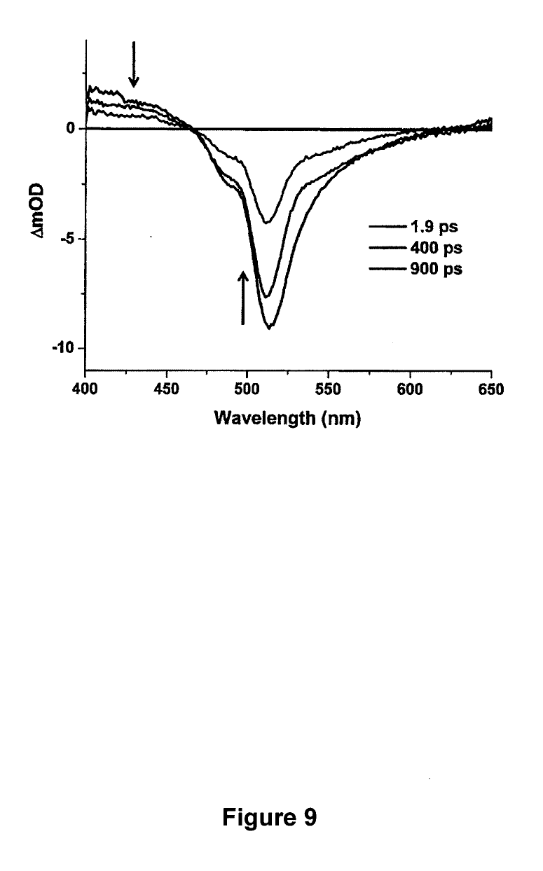

FIG. 9 shows the transient absorption of dyad 1 in toluene.

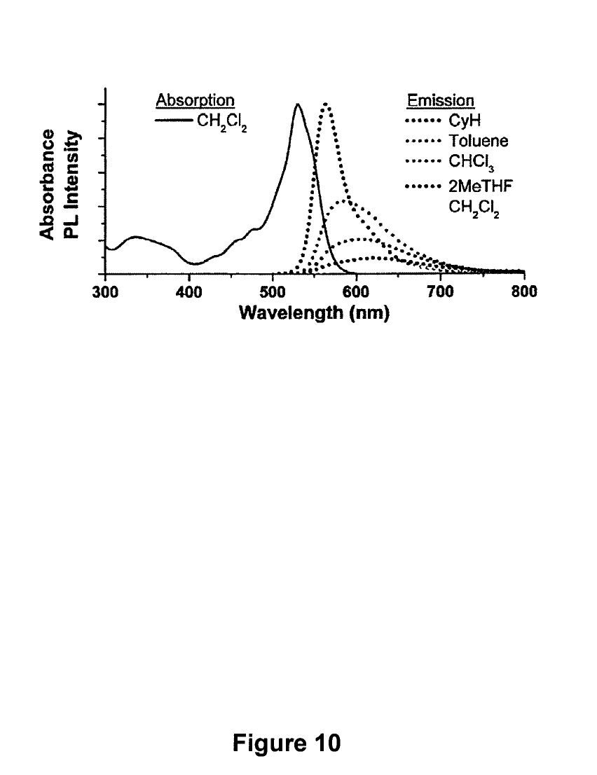

FIG. 10 shows the absorption spectra of dyad 4 in CH₂Cl₂ and emission spectra of 4 in solvents of varying polarity.

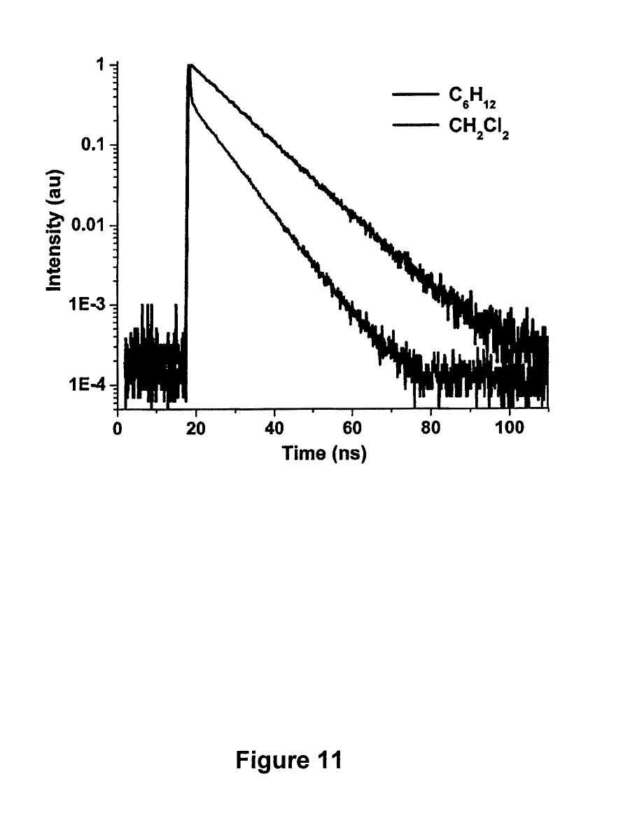

FIG. 11 shows the normalized emission decays of dyad 4 in cyclohexane (564 nm) and CH₂Cl₂ (651 nm) following excitation at 405 nm.

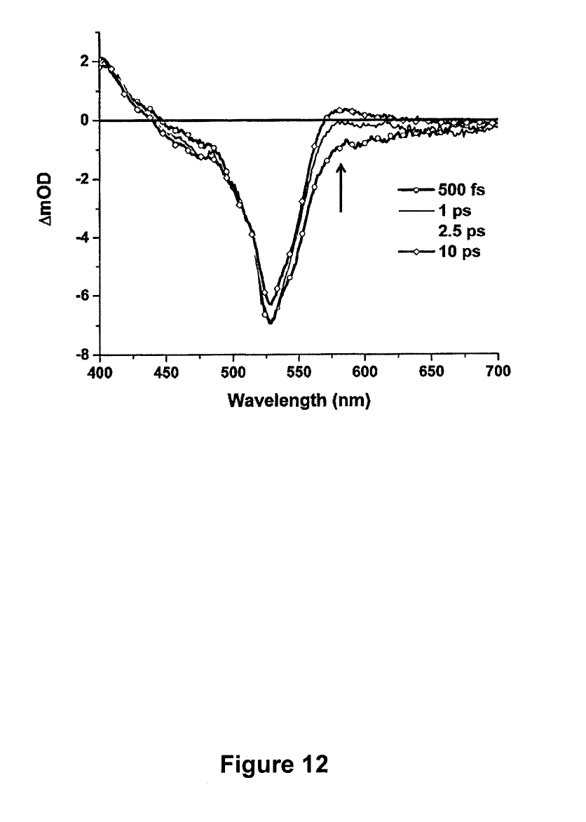

FIG. 12 represents the transient absorption of dyad 4 in CH₂Cl₂.

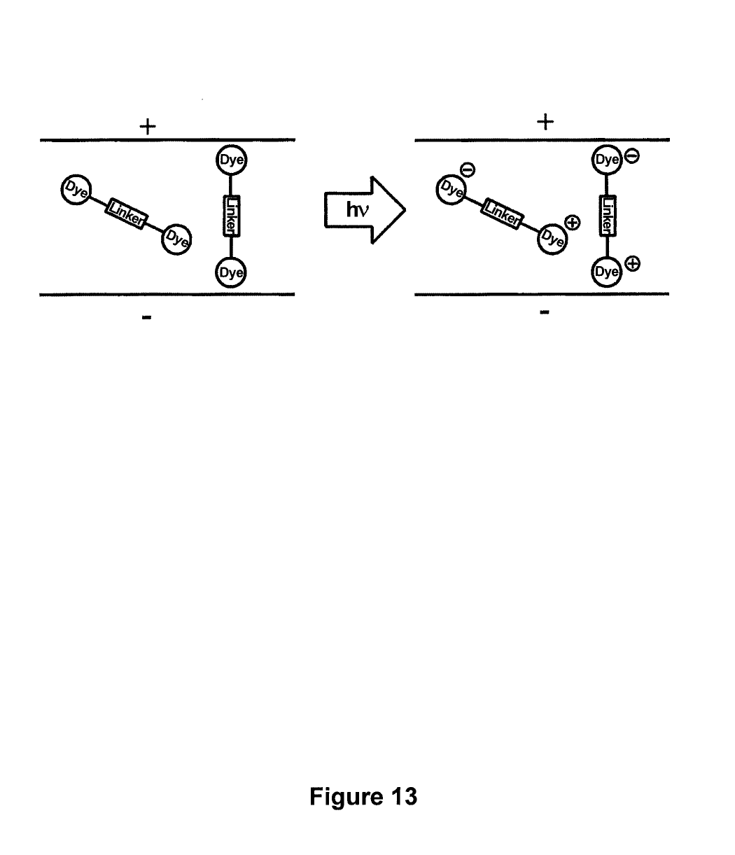

FIG. 13 represents the generation of stabilized intramolecular polaron pairs in the presence of an electric field.

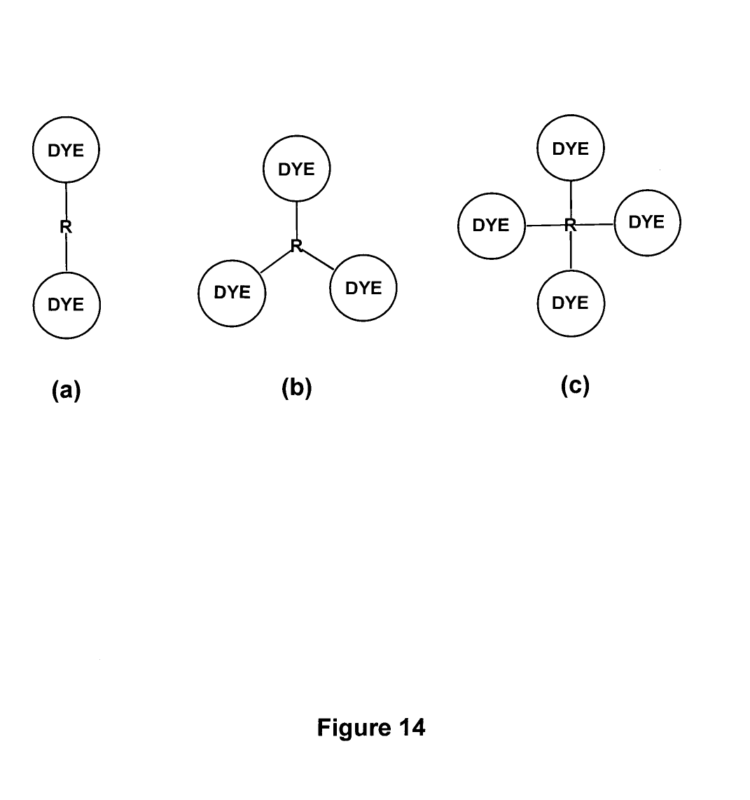

FIG. 14 represents methods for structuring symmetry-breaking ICT dyads, triads, and tetrads ((a), (b) and (c) respectively) where R represents the linking molecule between the dyes.

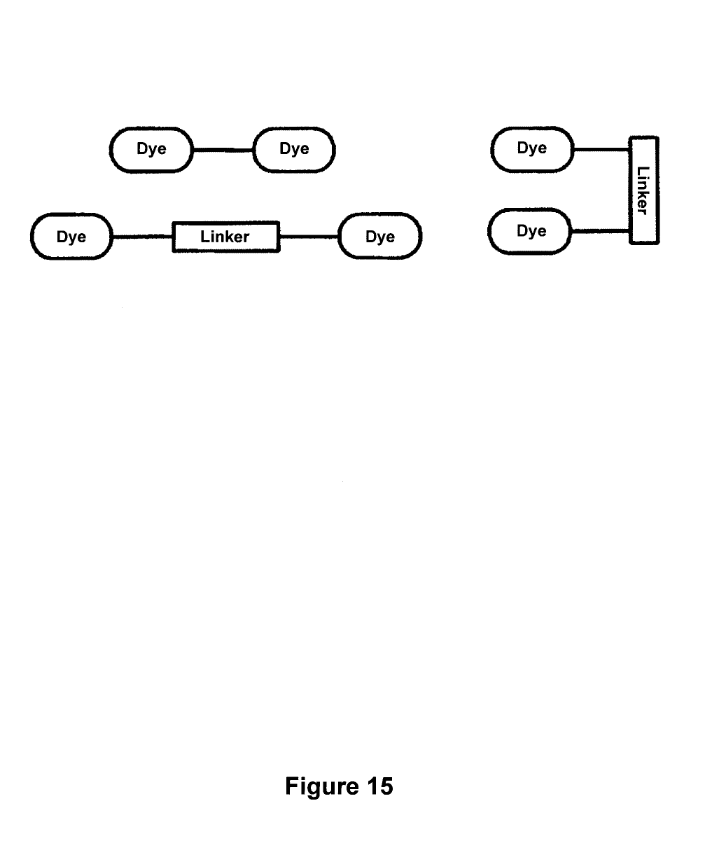

FIG. 15 represents methods for connecting two dyes to facilitate symmetry-breaking ICT.

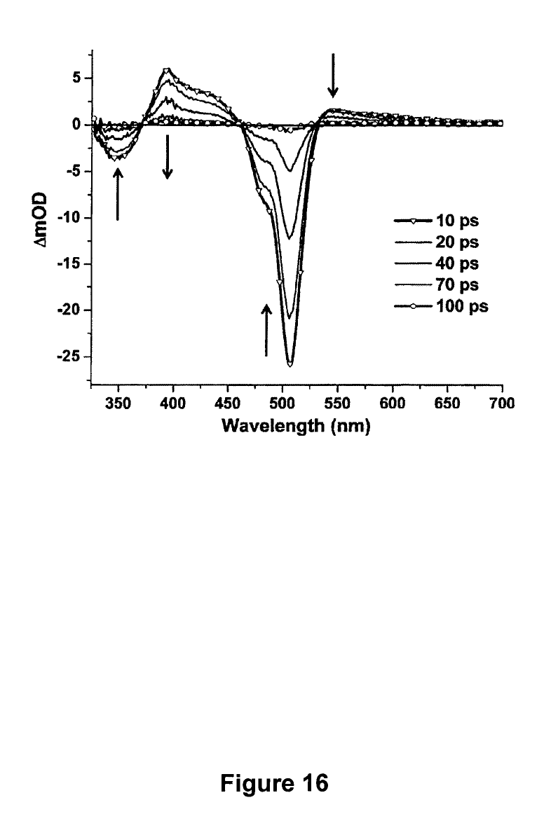

FIG. 16 shows the transient absorption of dyad 1 in acetonitrile with all transient spectral features completely relaxed within ca. 150 ps.

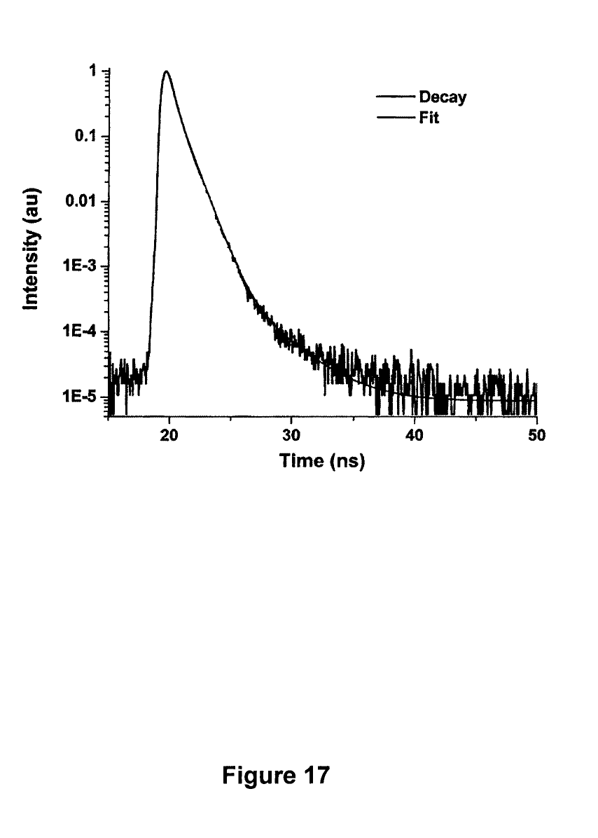

FIG. 17 represents time domain slices of transient absorption of dyad 1 in toluene.

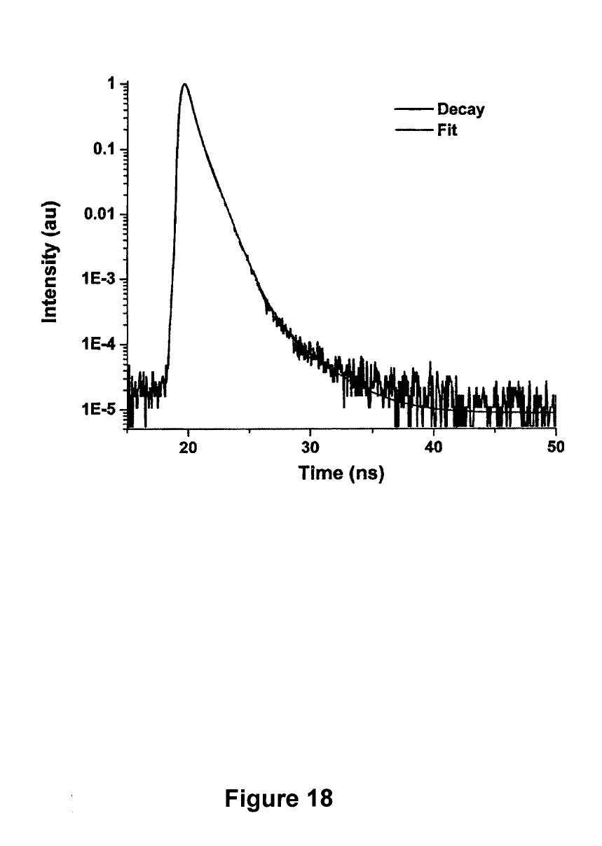

FIG. 18 shows the normalized emission decay of dyad 1 in toluene (535 nm) following excitation at 435 nm.

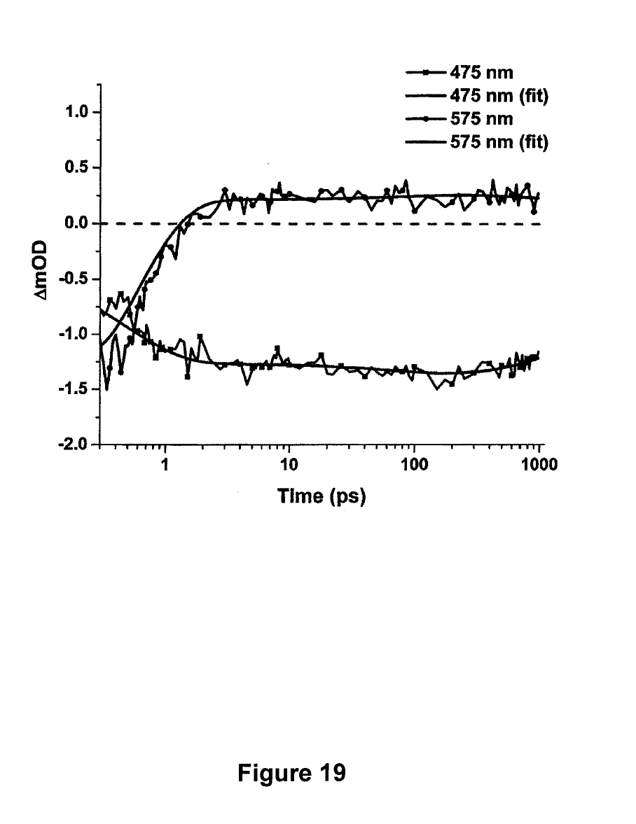

FIG. 19 represent time domain slices of transient absorptions at 475 and 575 nm with predicted traces based on kinetic parameters.

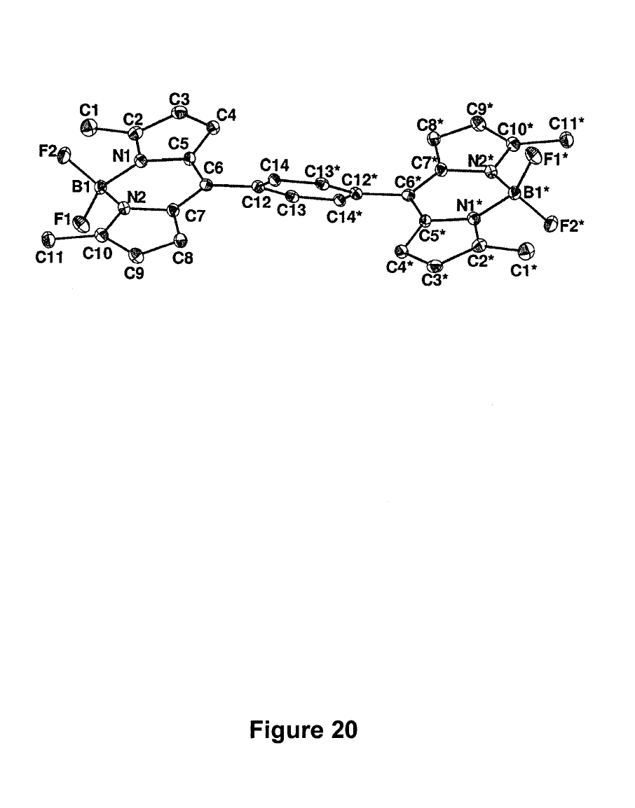

FIG. 20 shows the X-ray structure of dyad 1.

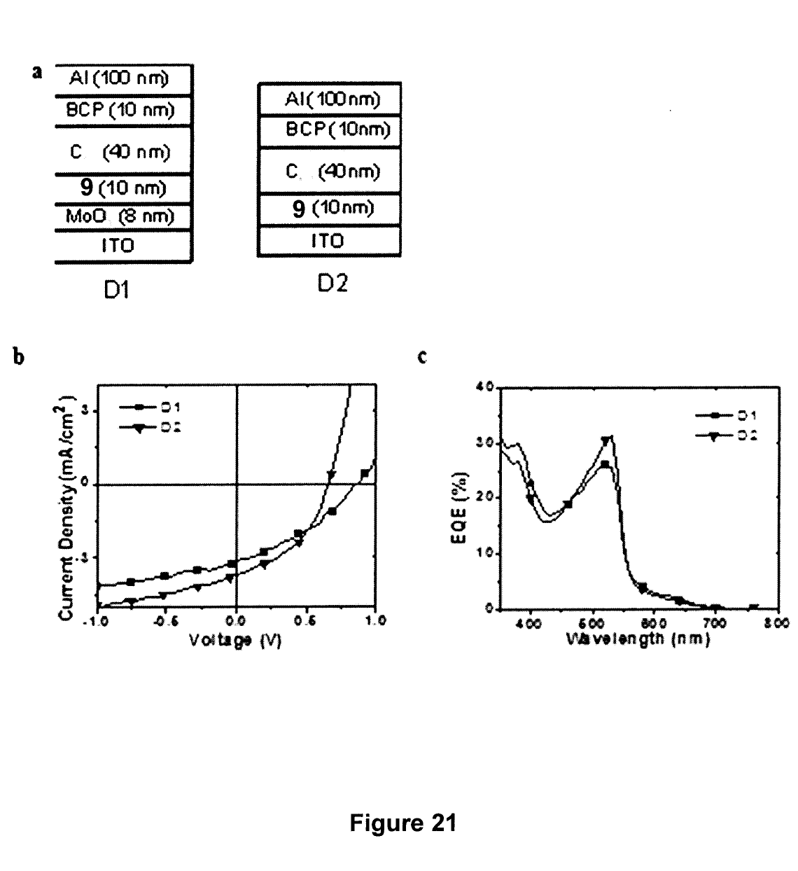

FIG. 21(a) shows device structure of an OPV using compound 9 of FIG. 3; FIG. 21(b) shows current-voltage characteristics of the OPV under AM1.5G illumination; and FIG. 21(c) shows external quantum efficiency (EQE).

One embodiment of the present disclosure relates to compounds that exhibit the light absorption and symmetry breaking properties required for applications in OPVs. By extension, compounds of the present disclosure mimic features seen in the photosynthetic reaction center.

Compounds that exhibit the light absorption and symmetry breaking properties required for applications in OPVs include, for example, higher order compounds, such as symmetrical dyads, triads, tetrads, etc. These compounds may populate intramolecular charge-transfer states in a polarizing medium by symmetry breaking, but cannot do so in the absence of a polarizing medium because of their symmetry. The higher order compounds preferably have at least C₂ symmetry and should have a luminescent lifetime of at least 1 ps to allow charge transfer to take place prior to other radiative or non-radiative decay processes.

In one embodiment, the higher order compounds may comprise, for example, dye compounds chosen from perylenes, malachites, xanthenes, cyanines, bipyridines, dipyrrins, coumarins, acridines, phthalocyanines, subphthalocyanines, porphyrins, and acenes. These dyes may be substituted with alkyl, H, electron donating or electron withdrawing groups at any position other than the linking site to control the physical and electronic properties of the dye. The relevant physical properties include solubility as well as sublimation and melting temperatures. The relevant electronic properties include the absorption and emission energies, as well as the oxidation and reduction potentials.

In another embodiment, the higher order compounds are chosen from the following dipyrrin chromophores:

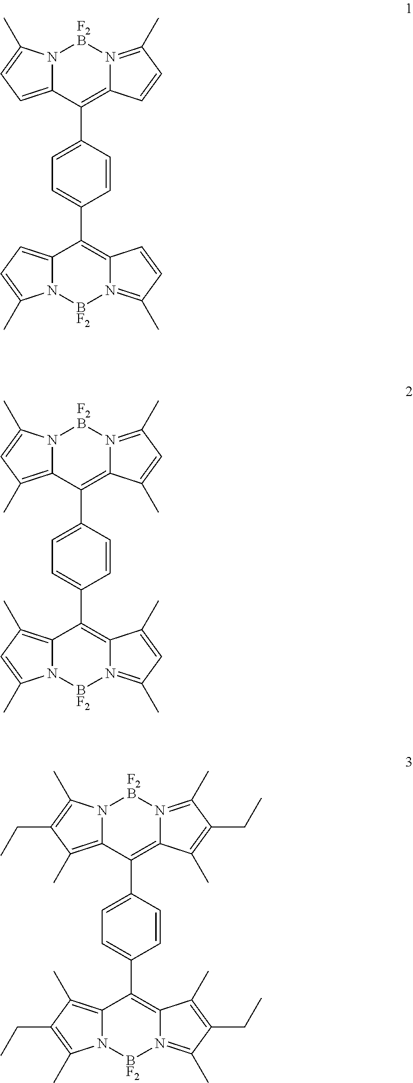

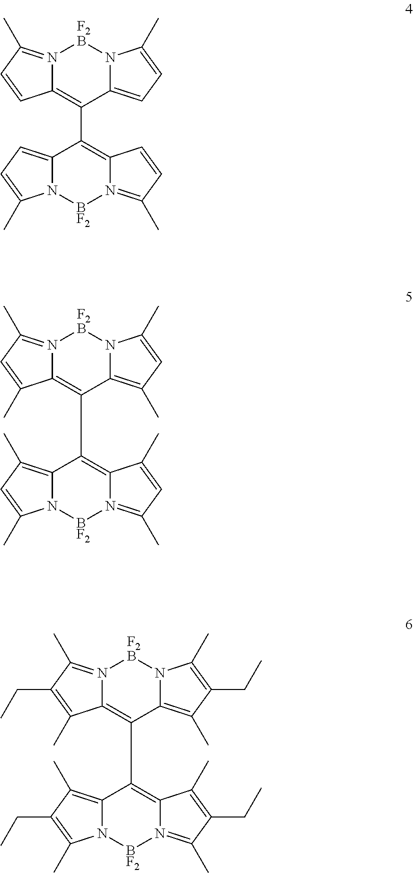

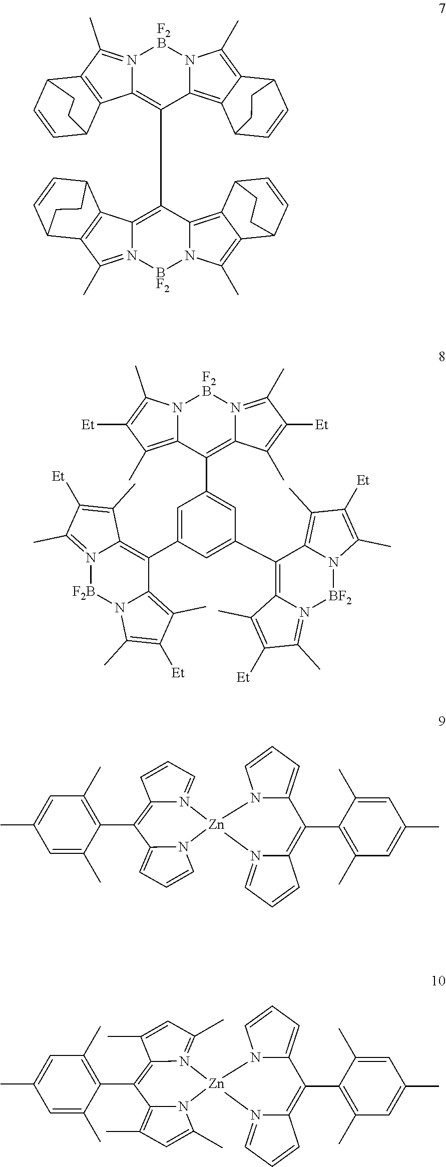

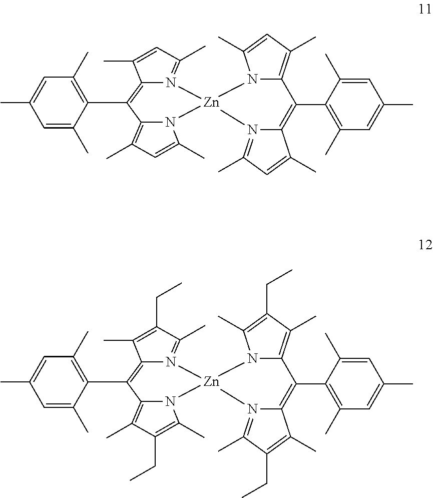

Another embodiment of the present disclosure provides for symmetry-breaking ICT compounds and their use as chromophores for the generation of electric-field-stabilized geminate polaron pairs. These polaron pairs collapse in the absence of an electric field, generating a high concentration of excitons and may be useful for the construction of organic lasers. In this process a large electric field is applied to drive the charge separation of excitons formed on light absorption and stabilize the geminate polaron pairs toward recombination. This was accomplished with a lightly doped matrix, where the dopant absorbs light and acts as one of the polarons (cation or anion), with the other polaron on the matrix material. The BODIPY dyads and related compounds described herein have donor and acceptor present in the same molecule (though in the absence of an electric field there is no driving force for excited-state charge separation), such that charge separation to form the geminate pairs can be efficiently achieved within the chromophore itself. This allows the chromophore to be doped into nonconductive host materials, preventing carrier leakage. The inherent C2 symmetry of the substituted porphryins ensure that nearly every molecule is present in an orientation that will promote charge separation (FIG. 13). An orientation that cannot be efficiently coupled with the electric field is one in which the plane of the dyad is perpendicular to the applied electric field. By using a randomly doped film, only a low percentage of the dopant is present in the nonproductive orientation.

In order to prove useful in solar cell applications, the constituent dye compounds must exhibit high absorptivity (ε>10⁻⁴M⁻¹ cm⁻¹) of light at some visible to near infrared wavelengths (350-1500 nm), for example, dyads of xanthenes dyes (e.g., fluorescein, eosins, and rhoadmines), coumarins, acridines, phthalocyanines, subphthalocyanines, porphyrins, acenes such as tetracene or pentacene, perylenes, malachites, cyanines, bipyridines, and dipyrrins, among others. In some solar cell applications, for example, single cell solar cells, the dye compounds may exhibit high absorptivity of light at some visible to near infrared wavelengths between 350 to 950 nm. In other solar cell applications, for example, tandem solar cells, the dye compounds may exhibit high absorptivity of light at some visible to near infrared wavelengths between 350 nm to at least 1200 nm. In an organic photodetector, the dye compounds may exhibit high absorptivity of light at some visible to near infrared wavelengths between 350 nm to at least 1500 nm.

The dyad (or triad, tetrad, etc.) must also possess an intramolecular charge-transfer (ICT) state that is energetically accessible from the photogenerated state in a polarizing medium. It is known that the energy of an ICT state can be approximated as:

E(ICT)=IP(D)−EA(A)+C+ΔEₛₒₗᵥ (1)

where IP(D) is the ionization potential of the donor, EA(A) is the electron affinity of the acceptor, C is the Coulombic stabilization of a neighboring cation and anion in the system, and ΔEₛₒₗᵥ is the stabilization of the ion pair by a surrounding polar environment (due to solvent or otherwise).

For the molecules proposed, the donor and acceptor are the same moiety, so a crude approximation of the energy of a symmetry-breaking ICT state can come from the energy required to pass one electron through the potential difference between the one-electron oxidation and reduction events, as determined by cyclic voltammetry or other electrochemical method. Since C and ΔEₛₒₗᵥ, only serve to stabilize the ICT state, this method will always lead to an overestimate of the energy. Thus, for example, if the difference in oxidation and reduction events for a dye is 2.50 V, then the energy of an ICT state for a dyad constructed from that dye will be less than 2.50 eV. To a first approximation, dimers (and higher order structures) of dyes with a first singlet excited state (S₁) energy greater than E_{ICT}−0.260 eV (i.e., E_{ICT} as determined by this method minus 10 kT) may be able to undergo symmetry-breaking intramolecular charge transfer at a polarizing donor/acceptor interface to facilitate charge separation in photovoltaics. The oxidation and reduction potentials and E₀₀ energies for some of the compounds in FIG. 3 are listed in Table 1.

TABLE 1
Oxidation and reduction potentials of molecules
from FIG. 3 in CH₂Cl₂.

| | | | | | E_{CT} (V) | |
|---|---|---|---|---|---|---|
| | 2^{nd} E_{-1/2} | 1^{st} E_{-1/2} | 1^{st} E_{+1/2} | Eₚₐ | 1^{st} (E_{red}-Eₒₓ) | E₀₀ (eV) |
| 1 | | −1.37 | 0.94 | | 2.31 | 2.38 |
| 2 | | −1.62 | | 0.83 | 2.43 | 2.41 |
| 3 | | −1.69 | 0.66 | | 2.34 | 2.32 |
| 4 | | −1.19 | | 0.97 | 2.16 | 2.25 |
| 6 | | −1.50 | 0.72 | | 2.22 | 2.20 |
| 9 | −2.33 | −1.93 | | 0.80 | 2.73 | 2.54 |
| 10 | −2.42 | −2.11 | | 0.60 | 2.71 | 2.48 |
| 11 | −2.79 | −2.35 | | 0.38 | 2.73 | 2.49 |
| 12 | −2.82 | −2.44 | | 0.24 | 2.68 | 2.40 |

The absorption profiles of the chromophores in FIG. 3 are generally similar to the monomer units of their respective dyes, indicating minimal excitonic coupling between the two (or three or more) dye units on the chromophore molecule. They are also generally invariant across different solvent polarities, since accessing any ICT state should first excite directly to the S₁ state. The absorption of the chromophores from FIG. 3 are listed in Table 2 for different solvents.

TABLE 2
Absorption and emission maxima for BODIPY dyes numbered in FIG. 3.

| Solvent | | 1 | 2 | 3 | 4 | 5 | 6 | 7 | 8 | 9 | 10 | 11 | 12 |
|---|---|---|---|---|---|---|---|---|---|---|---|---|---|
| | E_{T} (30) | | | | | | | | | | | | |
| | (kcal mol⁻¹)^{a} | | | | | | | | | | | | |
| Cyclohexane | 30.9 | 513 | NM | 525 | 523 | NM | 540 | NM | 537 | 484 | 493 | 489 | 506 |
| Toluene | 33.9 | 515 | 501 | 526 | 526 | 516 | 542 | 550 | 537 | 486 | 495 | 491 | 508 |
| Dichloromethane | 40.7 | 513 | 500 | 525 | 530 | 515 | 541 | 550 | 538 | 485 | 493 | 488 | 506 |
| Acetonitrile | 45.6 | 508 | 495 | 520 | 526 | 516 | 538 | 545 | 531 | 481 | 490 | NM | NM |
| | ET (30) | | | | | | | | | | | | |
| | (kcal mol−1)a | | | | | | | | | | | | |
| Cyclohexane | 30.9 | 538 | NM | 544 | 564 | NM | 592 | NM | 564 | 501 | 506 | 507 | 533 |
| Toluene | 33.9 | 540 | 524 | 545 | 574 | 587 | 601 | 584 | 564 | 503 | 509 | 509 | 533 |
| Dichloromethane | 40.7 | 538 | 522 | 543 | 651 | 624 | 635 | 601 | 566 | 495 | 511 | 509 | 528 |
| Acetonitrile | 45.6 | 531 | 522 | 538 | — | 678 | 680 | 671 | 553 | 490 | 508 | NM | NM |

^{a}Solvent polarity index,
^{b}No emission was observed in these solvents.
NM—No measurement taken in this solvent.

The fluorescence for each chromophore (Table 3) can be altered based on the solvent environment, as the increasing solvent polarity should stabilize access to the CT state and decrease the energy of that CT state. Thus, a red shift of any emissive CT state should be seen in the fluorescence spectra and is noted for directly linked dyads 4, 5, 6 and 7. Chromophores 9-12 illustrate separate CT bands that grow in as solvent polarity increases at longer wavelength. However, the rest of the chromophores seem to possess non-emissive CT states. Evidence for these CT states is seen when measuring the photoluminescent quantum yield (Table 3), which decreases for all candidates as solvent polarity increases. The decrease in quantum yield indicates there is some state that is increasingly non-emissive as solvent polarity increases.

TABLE 3
Photoluminescence quantum yields in varying solvents
of compounds from FIG. 3.

| | | PL quantum yield | | | | | |
|---|---|---|---|---|---|---|---|
| | E_{T} (30) (kcal | | | | | | |
| Solvent | mol⁻¹) | 1 | 2 | 3 | 4 | 5 | 7 |
| Cyclohexane | 30.9 | 0.052 | NM | NM | 0.780 | NM | NM |
| Toluene | 33.9 | 0.095 | 0.510 | 0.420 | 0.620 | 0.155 | 0.701 |
| Dichloromethane | 40.7 | 0.069 | 0.290 | 0.370 | 0.087 | 0.094 | 0.291 |
| Acetonitrile | 45.6 | <0.001 | 0.005 | 0.036 | — | 0.004 | 0.027 |
| | E_{T} (30) (kcal | | | | | | |
| Solvent | mol⁻¹) | 8 | 9 | 10 | 11 | 12 | |
| Cyclohexane | 30.9 | 0.281 | 0.414 | 0.700 | 0.180 | 0.172 | |
| Toluene | 33.9 | 0.130 | 0.333 | 0.190 | 0.138 | 0.134 | |
| Dichloromethane | 40.7 | 0.124 | 0.028 | 0.038 | 0.005 | 0.002 | |
| Acetonitrile | 45.6 | — | <0.001 | <0.001 | <0.001 | <0.001 | |

^{a}Solvent polarity index,
^{b}No emission was observed in these solvents
NM—no measurement taken.

Support for the formation of an ICT state in polar solvents was provided by femtosecond transient absorption measurements (Table 4). Excitation at a BODIPY wavelength (˜500 nm) in acetonitrile populates the S₁ state, as reflected by the appearance of a stimulated emission band from 525-600 nm for the BODIPY chromophores. Over the course of 10 ps, this band disappears concomitant with the rise of a weak induced absorption band peaked at ˜545 nm that matches absorption spectra reported for the BODIPY radical anion. A global fit to the data yields a rate formation of this ICT state (k_{CT}⁻¹). Subsequently, all transient spectral features decay with a rate constant given as k_{rec}⁻¹. The evidence of the CT state decreases as solvent polarity decreases from acetonitrile to dichloromethane to toluene and the recombination increases (becomes faster) correspondingly. We also note that as sterics increase (i.e. from 1 to 4), k_{rec}⁻¹ increases (becomes faster) and k_{rec}⁻¹ decreases (becomes slower).

TABLE 2
Rates of charge transfer (k_{CT}⁻¹) and charge recombination
(k_{rec}⁻¹) for the compounds in FIG. 3 in various solvents as
calculated using femtosecond transient absorption spectroscopy.

| TOLUENE | | | DICHLOROMETHANE | | | ACETONITRILE | | |
|---|---|---|---|---|---|---|---|---|
| Molecule | k_{CT}⁻¹ | k_{rec}⁻¹ | Molecule | k_{CT}⁻¹ | k_{rec}⁻¹ | Molecule | k_{CT}⁻¹ | k_{rec}⁻¹ |
| 1 | NA | NA | 1 | 18 ps | 1.6 ns | 1 | 4.8 ps | 34 ps |
| 2 | NA | NA | 2 | 136 ps | 3.2 ns | 2 | 53.0 ps | 196 ps |
| 3 | NA | NA | 3 | 165 ps | 2.5 ns | 3 | 74.0 ps | 288 ps |
| 4 | 4.5 ps | NA | 4 | 0.49 ps | 6.7 ns | 4 | 0.17 ps | 650 ps |
| 5 | 2.35 ps | 14.5 ps | 5 | 1.34 ps | 10.3 ns | 5 | 0.32 ps | 1.93 ns |
| 6 | 1.7 ps | 6.1 ns | 6 | 0.78 ps | 16.8 ns | 6 | 0.21 ps | 1.8 ns |
| 9 | 9.0 ps | NA | 10 | 5.7 ps | NA | 9 | 3.5 ps | NA |
| 10 | 5.7 ps | NA | 11 | NA | NA | 10 | 1.1 ps | NA |
| 11 | 2.6 ps | NA | 12 | NA | NA | 11 | 1 ps | NA |

NA—No measurement was taken because of instrument limitation or lack of CT formation.

In order to undergo such symmetry-breaking charge transfer, the dyes must be able to communicate electronically (though there need not be any ground-state interaction). Thus, the manner in which they are connected is important. There are a number of possible ways to link the dyes together to allow for symmetry breaking ICT to take place. Three examples are illustrated in FIG. 14 for bringing two, three, or four dyes together. For dyad-type structures, the two constituent dyes may be connected directly or through a linker that places them in linear or cofacial arrangements (FIG. 15). The linker must have higher energy optical transitions than the dyes to prevent direct energy transfer from the dye to the linker. Numerous linkers can be utilized, including saturated and unsaturated hydrocarbon linkers, with the most important requirement being that the linker must have ground state oxidation and reduction potentials, such that the linker is neither reduced nor oxidized by the photoexcited dye.

FIG. 14(a) contemplates a wide range of effectively divalent linkers. The linker could be a single atom, as illustrated for the Zinc based materials in compounds 9-12 of FIG. 3. This divalent group can also be a disubstituted arene, as illustrated in compounds 1-3 or a single bond as illustrated in compounds 4-7. One of skill in the art can envision a range of similar divalent linkers using other divalent atoms or effective divalent linkers constructed from aryl, fused aryl, such as naphthyl, anthryl, etc., alkyl, alkynyl, alkenyl, a single bond (R is a single bond), a heterocycle, a diazo or organosilane moiety. A tetravalent atom may also be used to link dyads, if the linker makes two covalent bonds to each dye. Such a connection with a carbon or silicon atom is termed a spiro connection and leads to a rigorous orthogonal of the two molecules bridged by the Spiro C or Si.

FIG. 14(b) illustrates three dyes disposed around a linker. This effectively trivalent linkage is demonstrated for 1,3,5-benzene in compound 8 of FIG. 3. This linkage could also be a trivalent metal atom such as Al or Ga, or a transition metal. These complexes are analogous to compounds 9-12 of FIG. 3, except the central metal atom would be surrounded by three bidentate ligands. One of skill in the art can envision a range of similar trivalent linkers using trivalent atoms or effective trivalent linkers constructed from aryl, fused aryl, such as naphthyl, anthryl, etc., alkyl, alkenyl, a heterocycle, or organosilane moiety.

FIG. 14(c) illustrates four dyes bound to a central linker. This linkage could be a tetravalent metal atom such as Ti, Zr or Hf. These complexes are analogous to compounds 9-12 of FIG. 3, except the central metal atom would be surrounded by four bidentate ligands. One of skill in the art can envision a range of similar tetravalent linkers using trivalent atoms or effective tetravalent linkers constructed from aryl, fused aryl, such as naphthyl, anthryl, etc., alkyl, alkenyl, a heterocycle, or organosilane moiety. A number of other geometries can be envisioned for higher-order structures, with the requirement that they be symmetric or pseudosymmetric in the ground state so that there is no driving force for ICT in the absence of a polarizing medium. Moreover, any interaction of the two molecules in the ground or excited state should not lead to the formation of an excited state lower in energy than the ICT, such as a triplet or excimeric excited state. These alternate excited states can exist, but they must be higher in energy than the ICT.

The symmetry-breaking charge transfer compounds preferably have at least C₂ symmetry, and this symmetry must be maintained upon linkage in the dyad, triad, tetrad, etc. The symmetry can be maintained by having the atom linking the dye to the linker lying on the C₂ axis, as in cynines, malachites, xanthenes and perylenes. Alternatively, the dye can be bound in such a way that the C₂ symmetry is retained in the bound structure—no atom bonded to the linkage center is on the C₂ axis.

To continue studies on charge and energy transfer reactions in BODIPY-porphyrin hybrids, one aspect of the disclosure provides for the synthesis and unusual symmetry-breaking ICT properties of symmetrical BODIPY dyads, wherein the units are connected through the meso position either indirectly by an intervening phenylene or directly through a C—C bond. Further investigation found the directly linked dyad to have excited-state properties that mimic behavior found in 9,9′-bianthryl.

Phenylene-bridged BODIPY dyad 1 of FIG. 3 was initially targeted due to its structural semblance to BODIPY-porphyrin hybrids.

Dyad 1 was prepared by acid-catalyzed condensation of terephthalaldehyde and 2-methylpyrrole, followed by oxidation with DDQ and difluoroborylation in the presence of N,N-diisopropylethylamine and boron trifluoride diethyl etherate. Analysis of dyad 1 by single-crystal x-ray diffraction reveals two coplanar BODIPY units rendered identical by a crystallographic center of symmetry (FIG. 20). The phenylene bridge is canted at an angle of 47° relative to the BODIPY planes, suggesting minimal steric encumbrance to partial rotation of the BODIPY units with respect to the linker. Thus, electronic superexchange, which requires interaction of the BODIPY and phenylene n-orbitals, should be possible across the phenylene bridge.

Absorption spectra of dyad 1 in solvents of varying polarity are nearly identical to the model compound 3,5Me₂BODIPY-Ph, indicating minimal ground-state interaction or excitonic coupling between the chromophores of dyad 1 (FIG. 6). Emission spectra of dyad 1 display small Stokes shifts that are nearly invariant in all 60 solvents. However, the photoluminescence quantum efficiencies (QE) are less than 0.1 and drop precipitously in the most polar solvents (Table 5). In contrast, the QE of 3,5Me₂BODIPY-Ph is 0.29 in cyclohexane, and declines to 0.17 in acetonitrile. The sharp decrease in the QE of dyad 1 indicates the possible formation of a non-emissive charge-transfer state that entails some degree of symmetry breaking since the BODIPY units are identical to the linker.

TABLE 5

| | E_{T}(30)^{a} | | | |
|---|---|---|---|---|
| | (kcal | λ_{max, ab}λ_{max, em} | λ_{max, ab}λ_{max, em} | |
| Solvent | mol⁻¹) | s(nm) | s(nm) | Φ |
| Cyclohexane | 30.9 | 513 | 538 | 0.052 |
| Toluene | 33.9 | 515 | 540 | 0.095 |
| 2-Methyltetra- | 36.5 | 511 | 540 | 0.046 |
| hydrofuran | | | | |
| Chloroform | 39.1 | 515 | 538 | 0.097 |
| Dichloromethane | 40.7 | 513 | 538 | 0.069 |
| Acetone | 42.2 | 509 | 534 | <0.001 |
| N,N-Dimethyl- | 43.2 | 512 | 536 | <0.001 |
| formaide | | | | |
| Acetonitrile | 45.6 | 508 | 531 | <0.001 |

^{a}Solvent polarity index

The potential for dyad 1 to undergo symmetry-breaking ICT was examined by electrochemistry. Cyclic voltammetry of dyad 1 revealed a reversible reduction (E_{1/2}=−1.37 V) and an irreversible oxidation (EPA=940 mV, both versus Fc/Fc⁺). The difference between oxidation and reduction values (2.31 V) indicates that the S₁ state of dyad 1 (E₀₀=2.38 eV in cyclohexane) should be energetic enough to undergo ICT, as previously discussed by Zander and Rettig.

Support for the formation of an ICT state in polar solvents was provided by femtosecond transient absorption measurements (FIG. 8). Excitation of dyad 1 at 508 nm in acetonitrile populates the S₁ state, as reflected by the appearance of a stimulated emission band from 525-600 nm that matches the S₁ emission line shape. Over the course of 10 ps, this band disappears concomitant with the rise of a weak induced absorption band peaked at 545 nm that matches absorption spectra reported for the BODIPY radical anion. A global fit to the data (FIG. 8(b)) yields a rate of 4.8 ps for the formation of this ICT state. Subsequently, all transient spectral features decay with a rate constant of 34 ps, indicating a fast non-radiative return to the S₀ state, consistent with asymmetric dyads incorporating a BODIPY acceptor. On other hand, excitation of dyad 1 in toluene leads to formation of an S₁ state that decays at a rate consistent with the lifetime determined from emission studies (τ=850 ps).

The importance of twisting and other structural changes of ICT excited states in donor/acceptor molecules has been extensively explored. Additionally, rotation of meso-aryl substituents relative to BODIPY chromophores has previously been invoked as a major pathway for non-radiative deactivation. In the present case, facile rotation of the phenylene bridge in dyad 1 is also what likely allows the ICT state to undergo ultrafast direct surface crossing to the ground state. Thus, these studies were extended using dyad 4 of FIG. 3, with the two BODIPY units linked directly 35 at the meso position by a C—C bond, for which rotational freedom should be significantly restricted. Dyad 4 was prepared in low yield (<3%) from 1,1,2,2-tetrakis(5-methyl-1H-pyrrol-2yl)ethene, which in turn was synthesized by a McMurry reaction, using standard oxidation and difluoroborylation conditions (Eq I). Although X-ray quality single crystals of dyad 4 have not been obtained, structure minimization using DFT (B3LYP/63Ig*) methods indicated that the planar BODIPY units of dyad 4 have local geometries similar to those of dyad 1, and are canted at a dihedral angle of 71° with respect to each other.

Absorption spectra of dyad 4 are nearly invariant across several solvents and are similar to that of dyad 1 and other BODIPY chromophores. Slight splitting of the primary (S₀→S₁) absorption band at 530 nm indicates a modest degree of exciton coupling between the BODIPY units. Fluorescence spectra, on the other hand, were dramatically affected by solvent. A small Stokes shift and high quantum efficiency were observed in cyclohexane. A progressive red-shift in the emission wavelength was observed with increasing solvent polarity, with concomitant broadening and decrease in QE (FIG. 10 and Table 6). The spectra indicated that dyad 4 has a nonpolar ground state and a significantly higher dipole moment in the excited state, even though the two constituent chromophores are identical. Similar behavior was observed for the 9,9′-bianthryl molecule.

TABLE 6

| | E_{T}(30)^{a} | | | |
|---|---|---|---|---|
| | (kcal | λ_{max, ab}λ_{max, em} | λ_{max, ab}λ_{max, em} | |
| Solvent | mol⁻¹) | s(nm) | s(nm) | Φ |
| Cyclohexane | 30.9 | 523 | 564 | 0.78 |
| Toluene | 33.9 | 526 | 574 | 0.62 |
| 2-Methyltetra- | 36.5 | 524 | 620 | 0.18 |
| hydrofuran | | | | |
| Chloroform | 39.1 | 526 | 585 | 0.35 |
| Dichloromethane | 40.7 | 530 | 651 | 0.087 |
| Acetone | 42.2 | 528 | —^{b} | —^{b} |
| N,N-Dimethyl- | 43.2 | 530 | —^{b} | —^{b} |
| formaide | | | | |
| Acetonitrile | 45.6 | 526 | —^{b} | —^{b} |

^{a}Solvent polarity index;
^{b}No emission observed

Dyad 4 exhibited a simple first-order luminescence decay in cyclohexane (τ=9.3 ns), whereas biexponential decay was observed in dichloromethane, comprised of a fast component (<200 ps) accompanied by a longer-lived (ca 7 ns) decay. (FIG. 11) The non-radiative decay rate of dyad 4 (kₙᵣ=1.4×10⁸ S⁻¹) in CH₂Cl₂ is more than two orders of magnitude slower than that of dyad 1 in acetonitrile. These results indicate that a local S₁ state formed upon photoexcitation of dyad 4 undergoes ultrafast transformation to an emissive ICT state by solvent-induced symmetry breaking in polar solvents.

Femtosecond transient absorption spectroscopy in CH₂Cl₂ was used to further illuminate the charge-transfer behavior of dyad 4 in polar media. The S₁ state observed upon excitation at 508 nm quickly evolves (k_{IC}⁻¹=570±80 fs) to produce an excited state that absorbs at 580 nm, consistent with the formation of a BODIPY radical anion (FIG. 12). In contrast to the ICT state observed in dyad 1 however, the spectral features associated with the ICT state in dyad 4 show only minimal change in amplitude over the course of 1 ns, indicating that this state has a lifetime comparable to that of the emissive state.

Although several biacenes display similar luminescent properties, to the best of our knowledge dyad 4 represents the first example of a dyad that combines symmetry-breaking formation of an emissive ICT state with intense absorption in the visible region of the spectrum. While porphyrins are in many respects related to dipyrrins, the meso-linked porphyrin analogues of dyad 4 do not undergo symmetry-breaking ICT because formation of such an excited state is endothermic with respect to the S₁ state. BODIPY dyads directly linked at the α- or β positions also do not exhibit this sort of emissive behaviour. However, Benniston et al. have reported a hybrid of dyad 4 and 9,9′-bianthryl, a meso-linked 9-anthracenyl-BODIPY compound, that readily forms an emissive ICT state in polar solvents, akin to an exciplex.

These directly linked dyads serve as a visible-light-absorbing analogue of 9,9′-bianthryl.

BODIPY dyads 1 and 4 lead to formation of ICT states in polar media by solvent-induced symmetry breaking. The further presence of strong absorption at visible wavelengths enables these molecules to mimic features seen in the photosynthetic reaction center. Model systems that possess both these characteristics are rare. Differing degrees of rotational freedom in the dyads significantly alter the behavior of the ICT state. Whereas dyad 1 undergoes rapid non-radiative decay to the ground state, the more hindered dyad 4 has a long-lived ICT state with moderate-to-high fluorescence quantum efficiency.

Femtosecond transient absorption measurements were performed using a Ti:sapphire regenerative amplifier (Coherent Legend, 3.5 mJ, 35 fs, 1 kHz repetition rate). Approximately 10% of the amplifier output was used to pump a type II OPA (Spectra Physics OPA-80OC) resulting in the generation of excitation pulses centered at 508 nm with 11.5 nm of bandwidth. At the sample position, the pump was lightly focused to a spot size of 0.29 mm (FWHM) using a 50 cm CaF₂ lens. Probe pulses were generated by focusing a small amount of the amplifier output into a rotating CaF₂ plate, yielding a supercontinuum spanning the range of 320-950 nm. A pair of off-axis aluminum parabolic mirrors collimated the supercontinuum probe and focused it into the sample.

Samples consisting of either dyad 1 or 4 dissolved in the appropriate solvent were held in a 1 cm path length quartz cuvette and had a peak optical density between 0.13 and 0.18. Data were collected for perpendicularly oriented pump and probe. This allowed for the suppression of scatter originating from the pump beam by passing the probe through an analyzing polarizer after the sample. A spectrograph (Oriel MS127I) was used to disperse the supercontinuum probe onto a 256 pixel silicon diode array (Hamamatsu) that enabled multiplex detection of the transmitted probe as a function of wavelength. An optical chopper was used to block every other pump pulse, allowing for differential detection of the pump-induced changes in the probe. The data in the main text represent the average probe transmission change measured for 1500 on/off pump pulse pairs.

At early time delays, a strong non-resonant signal from the sample cell and solvent is observed, but relaxes within 300 fs. Careful measurement of this non-resonant signal enabled its partial subtraction from the transient data. The non-resonant solvent response also provided a measure of the temporal dispersion of the supercontinuum probe resulting from propagation through the CaF₂ plate and sample. The presented data have been corrected to account for this dispersion.

Transient experiments were carried out using a pump fluence of 265 uJ/cm². Based on the cross sections of dyads 1 and 4, at this fluence we expect less than one excitation per dyad molecule. Transient experiments carried out at a fluence of 135 uJ/cm² scaled linearly with those measured at higher fluence and yielded similar fit time constants, suggesting that annihilation processes do not contribute to the signal.

The measured transient spectra indicate that in dyad 1, the initially excited population evolves over time to form an ICT state that non-radiatively returns to the ground state while in dyad 4 the ICT state persists for nanosecond or longer time scales. To obtain rates for the formation of the ICT state in either dyad as well as for the non-radiative repopulation of the ground state in dyad 1, it is assumed that the transient spectra can be described using a three-state model governed by a series of sequential first order rate processes:

$${S}_{I} {\to }^{{K}_{ICT}} ICT {\to }^{{K}_{nr}} {S}_{o} \qquad ( S1 )$$

where k_{ICT} and kₙᵣ denote the rates for the formation of the ICT state and non-radiative return to the ground state, respectively. On the basis of Eq S1 we can linearly decompose the transient spectra of either dyad, S(λ,t), as:

S(λ,t)=c_{S1}(t)σ_{S1}(λ)+c_{ICT}(t)σ_{ICT}(λ). (S2)

Here, c_{S1}(t) and c_{ICT}(t) denote their time-dependent populations of the S₁ and ICT states of a given dyad, while σ_{S1}(λ) and σ_{ICT}(λ) represent the time-independent characteristic transient absorption spectrum that results from the population of either state. These basis spectra contain both positive features due to excited state absorption and negative going peaks due to a combination of stimulated emission and ground state depopulation (bleaching).

The time dependent behavior of C_{S1}(t) and C_{ICT}(t) is given by the solution to the set of coupled differential equations implied by Eq. S1:

$$\frac{d {c}_{SI} ( t )}{d t} = {I}_{o} - {k}_{ICT} {c}_{SI} ( t ) \\ \frac{d {c}_{ICT} ( t )}{d t} = {k}_{ICT} {C}_{SI} ( t ) - {k}_{nr} {c}_{ICT} ( t ) \qquad ( S3 )$$

where I₀ is the initial population placed in the SI state by the excitation pulse. To model the behavior of dyad 1 in acetonitrile, both k_{ICT} and kₙᵣ were determined through a least squares minimization routine. Since transient spectra of 4 in dichloromethane showed minimal signatures of non-radiative relaxation to the ground state over the course of the experimental time window (1 ns), kₙᵣ was constrained to match the non-radiative decay rate of 4 determined by luminescence measurements (1.4×10⁸ S⁻¹).

The fits that result from the global analysis model appear alongside the experimental transients plotted in FIG. 8(b) and FIG. 19. Overall, the agreement between the experimental data and our model is quite good. Regarding 1, FIG. 8(b) shows that the disclosed model reproduces the growth of the induced absorption at 550 nm resulting from formation of the ICT state (1/k_{ICT}=4.8 ps). This feature subsequently decays at a rate that matches the recovery of the ground state bleach at 507 om (1/kₙᵣ=34 ps), indicating that decay of the ICT state results in refilling of the ground state. In contrast, the ICT state of dyad 4 develops nearly an order of magnitude faster than that of dyad 1 (1/k_{ICT}=570 fs) as evidenced by the rapid formation of an induced absorption band at 575 nm (FIG. 19), but shows no indication of ground state reformation over the experimental time window (1 ns).

Crystal Data and Structure Refinement for Dyad 1

| Empirical formula | C₂₈H₂₄B₂F₄N₄ | |
|---|---|---|
| Formula weight | 514.13 | |
| Temperature | 123(2) K | |
| Wavelength | 0.71073 \acute{Å} | |
| Crystal System | Orthorhombic | |
| Space group | Pbca | |
| Unite cell dimensions | a = 12.808(3) \acute{Å} | α = 90°. |
| | b = 12.205(2) \acute{Å} | β = 90°. |
| | c =15.019(3) \acute{Å} | γ = 90°. |

| | |
|---|---|
| Volume | 2347.8(8) \acute{Å}³ |
| Z | 4 |
| Density (calculated) | 1.455 Mg/m³ |
| Absorption coefficient | 0.108 mm⁻¹ |
| F(000) | 1064 |
| Crystal Size | 0.10 × 0.09 × 0.07 mm³ |
| Theta range for data collection | 2.67 to 27.55°. |
| Index ranges | −16 <= h <= 16, −10 <= k <= |
| | 15, −19 <= l <= 18 |
| Reflections collected | 13598 |
| Independent reflections | 2688 [R(int) = 0.1065] |
| Completeness to theta = 25.00° | 100.0% |
| Absorption correction | Semi-empirical from equivalents |
| Max. and min. transmission | 0.7456 and 0.5788 |
| Refinement method | Full-matrix least-squares on F² |
| Data/restraints/parameters | 2688/0/174 |
| Goodness-of-fit on F² | 1.119 |
| Final R indices [I > 2sigma(I)] | R1 = 0.0571, wR2 = 0.0838 |
| R indices (all data) | R1 = 0.1215, wR2 = 0.0926 |
| Largest diff. peak and hole | 0.285 and −0.209 e.\acute{Å}³ |

The combination of strong visible-light absorption and excited-state ICT make dyads 1 and 4, as well as their analogues, promising candidates for applications such as those described above, where organic materials with accessible ICT states efficiently move singlet excitation energy to a D/A interface before undergoing intramolecular charge transfer to maximize the rate of forward electron transfer while minimizing the reverse interfacial recombination process.

Thus, in one embodiment, the present disclosure provides for an organic photosensitive optoelectronic device comprising:

at least one compound chosen from a higher order structure, wherein said compound's absorptivity of light at some visible wavelength is about >10⁴ M⁻¹ cm⁻¹, and wherein said compound is capable of undergoing symmetry-breaking intramolecular charge transfer in the excited state. The organic photosensitive devices disclosed herein can be, for example, an organic photodetector, or an organic solar cell.

In one embodiment, the at least one compound is chosen from dyads of xanthenes dyes, coumarins, acridines, phthalocyanines, subphthalocyanines, porphyrins, acenes, perylenes, malachites, cyanines, bipyridines, and dipyrrins. In another embodiment, the compound is chosen from even higher order structures such as triads and tetrads.

In one embodiment, the intramolecular charge transfer occurs in a polarizing medium.

In one embodiment, the intramolecular charge transfer in the excited state is energetically accessible from a photogenerated S₁ state in a polarizing medium.

In one embodiment, the dyads may be connected either directly or through a linker (such as saturated or unsaturated linear or branched hydrocarbons, or aromatic rings, e.g., phenylene, or constructed from aryl, fused aryl, such as naphthyl, anthryl, etc., alkyl, alkynyl, alkenyl, a heterocycle, a diazo or organosilane moiety), such that the dyads are arranged in linear or cofacial fashion.

In one embodiment, the compound is 1,4-Bis(4,4-difluoro-3,5-dimethyl-4-bora-3a,4a-diaza-s-indacene-8-yl)benzene or a salt or hydrate thereof. In another embodiment, the compound is Bis(4,4-difluoro-3,5-dimethyl-4-bora-3a,4a-diaza-s-indacene-8-yl), or a salt or hydrate thereof.

A further embodiment is directed to a process for preparing 1,4-Bis(4,4-difluoro-3,5-dimethyl-4-bora-3a,4a-diaza-s-indacene-8-yl)benzene, or a salt or hydrate thereof, comprising treating a mixture comprising terephthalaldehyde and 2-methylpyrrole with a halogenated carboxylic acid, an oxidizing agent, and Lewis acid to form 1,4-Bis(4,4-difluoro-3,5-dimethyl-4-bora-3a,4a-diaza-s-indacene-8-yl)benzene. In further embodiments, the halogenated carboxylic acid can be trifluoroacetic acid, the oxidant can be DDQ and the Lewis acid can be boron trifluoride diethyl etherate.

An additional embodiment is directed to a process for preparing Bis(4,4-difluoro-3,5-dimethyl-4-bora-3a,4a-diaza-s-indacene-8-yl), or a salt or hydrate thereof, comprising treating a mixture comprising a first Lewis acid and a transition metal with a mixture comprising bis(5-methyl-1H-pyrrol-2-yl)methanone to form 1,1,2,2-tetrakis(5-methyl-1H-pyrrol-2-yl)ethene; and treating a mixture comprising 1,1,2,2-tetrakis(5-methyl-1H-pyrrol-2-yl)ethene and a base with an oxidant and second Lewis acid to form Bis(4,4-difluoro-3,5-dimethyl-4-bora-3a,4a-diaza-s-indacene-8-yl). In further embodiments, the first Lewis acid can be TiCl4, the transition metal can be zinc, the base can be triethylamine, the oxidant can be DDQ, and the second Lewis acid can be boron trifluoride diethyl etherate.

The present disclosure also provides for methods of making an organic photosensitive device comprising an organic photosensitive optoelectronic device, wherein said organic photosensitive optoelectronic device comprises:

at least one compound chosen from a dyad or higher order structure, wherein said compounds absorptivity of light at some visible wavelength is about >10⁴ M⁻¹ cm⁻¹, and wherein said compound is capable of undergoing symmetry-breaking intramolecular charge transfer in the excited state.

### EXAMPLES

### General Considerations

2-Methylpyrrole was obtained by a Wolff-Kishner reduction of pyrrole-2-carboxaldehyde as previously described. 1-Methyl-4,7-dihydro-2H-4,7-ethanoisoindole was prepared by lithium aluminum hydride reduction of the corresponding ester according to literature procedure. All other reagents were purchased from commercial vendors and used without further purification. All air-sensitive manipulations were performed using standard Schlenk techniques as needed, following the procedures indicated below for each preparation. NMR spectra were recorded at ambient temperature on Varian Mercury 400 MHz and 600 MHz spectrometers. ¹H chemical shifts were referenced to residual solvent. UV-vis spectra were recorded on a Hewlett-Packard 4853 diode array spectrophotometer. Steady-state emission experiments were performed using a Photon Technology International QuantaMaster Model C-60SE spectrofluorimeter. Fluorescence lifetime measurements were performed by a time-correlated single-photon counting method using an IBH Fluorocube lifetime instrument by equipped with a 405 nm or 435 nm LED excitation source. Quantum efficiency measurements were carried out using a Hamamatsu C9920 system equipped with a xenon lamp, calibrated integrating sphere and model C10027 photonic multichannel analyzer.

### Example 1

### General Reaction Scheme for Phenylene Bridged Dyads 1, 2 and 3 of FIG. 3

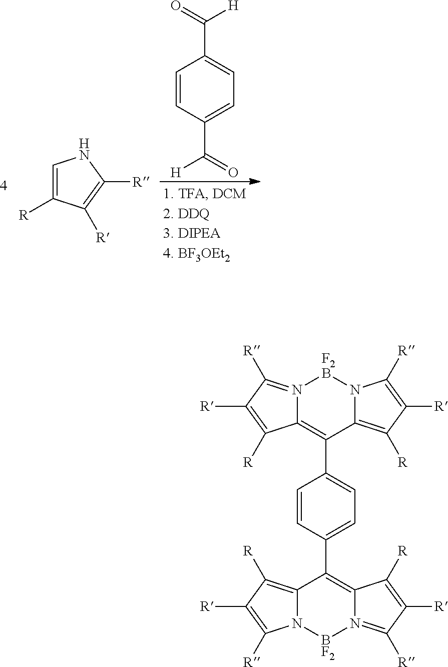

Phenylene Bridged Dyad 1.

Terephthalaldehyde (762 mg, 5.68 mmol) and 2-methylpyrrole (2.03 g, 23.3 mmol) were dissolved in dry, degassed CH₂Cl₂ (40 mL) under N₂. The resulting solution was further degassed for 10 min, and trifluoroacetic acid (64 μL, 0.84 mmol) was added in two portions, causing the solution to darken immediately, and the reaction was allowed to proceed with stirring for 2 h. DDQ (2.58 g, 11.4 mmol) was added in one portion, causing an immediate color change to dark red-orange, and the resulting mixture was stirred for 13 h. N,N-Diisopropylethylamine (8.0 mL, 46 mmol) was added at once, causing a color change to dark brown, and stirring was continued for 15 min. Boron trifluoride diethyl etherate (8.0 mL, 64 mmol) was added slowly over the course of 1 min, causing the mixture to warm slightly. After 45 min, the mixture was quenched with NaHCO₃ (5% aq, 200 mL) and stirred vigorously for 2 h. Organics were removed and washed with Na₂SO₃ (10% aq, 2×100 mL), HCl (5% aq, 1×100 mL), and brine (2×100 mL). The organics were removed and dried with MgSO₄, filtered, and concentrated to a dark solid, which was purified by column chromatography (SiO₂ gel, CHCl₃ eluent, R_{f}=0.5) to afford dyad 1 as a pure red-orange solid (200 mg, 7%). UV-vis (CH₂Cl₂) λₘₐₓ: 350, 513. ¹H NMR (CDCl₃): δ 7.62 (s, 4H, phenylene Ar—H), 6.76 (d, ³J_{HH}=4.4 Hz, 4H, BODIPY Ar—H), 6.31 (d, ³J_{HH}=4.4 Hz, 4H, BODIPY Ar—H), 2.68 (s, 12H, —CH₃). ¹³C NMR (CDCl₃): δ 158.38, 141.14, 135.94, 134.47, 130.41, 130.32, 119.91, 15.13. MALDI, m/z for C₂₈H₂₄B₂F₄N₄ calcd 514.21 (100%), 513.22 (51%), 515.22 (33%). found 512.83 (100%), 511.83 (51%), 513.82 (45%).

Phenylene Bridged Dyad 2.

Terephthalaldehyde (1 g, 7.55 mmol) and 2,4-dimethylpyrrole (2.98 g, 31.3 mmol) were dissolved in dry, degassed CH₂Cl₂ (30 mL) under N₂. The resulting solution was further degassed for 10 min, and trifluoroacetic acid (1 drop) was added and the reaction was allowed to proceed with stirring for 5 h. DDQ (3.38 g, 14.9 mmol) was added in one portion, and the resulting mixture was stirred overnight. N,N-Diisopropylethylamine (10.4 mL, 59.6 mmol) was added at once, and stirring was continued for 15 min. Boron trifluoride diethyl etherate (7.5 mL, 59.6 mmol) was added. After 45 min, the mixture was quenched with NaHCO₃ (5% aq, 200 mL) and stirred vigorously for 2 h. Organics were removed and washed with Na₂SO₃ (10% aq, 2×100 mL), HCl (5% aq, 1×100 mL), and brine (2×100 mL). The organics were removed and dried with MgSO₄, filtered, and concentrated to a dark solid, which was purified by column chromatography (SiO₂ gel, CH₂Cl₂ eluent) to afford dyad 2 as a pure red-orange solid (427 mg, 10%). ¹H NMR (CDCl₃): δ 7.52 (s, 4H, phenylene Ar—H), 6.01 (s, 4H, BODIPY Ar—H), 2.57 (s, 12H, —CH₃), 1.53 (s, 12H, —CH₃).

Phenylene Bridged Dyad 3.

Terephthalaldehyde (1 g, 7.46 mmol) and 2,4-dimethyl-3-ethylpyrrole (3.67 g, 29.8 mmol) were dissolved in dry, degassed CH₂Cl₂ (40 mL) under N₂. The resulting solution was further degassed for 10 min, and trifluoroacetic acid (1 drop) was added and the reaction was allowed to proceed with stirring for 2 h. DDQ (3.39 g, 14.9 mmol) was added in one portion, causing an immediate color change to dark red-orange, and the resulting mixture was stirred for 13 h. N,N-Diisopropylethylamine (10.4 mL, 59.7 mmol) was added at once, causing a color change to dark brown, and stirring was continued for 15 min. Boron trifluoride diethyl etherate (7.5 mL, 59.7 mmol) was added slowly over the course of 1 min, causing the mixture to warm slightly. After 45 min, the mixture was quenched with NaHCO₃ (5% aq, 200 mL) and stirred vigorously for 2 h. Organics were removed and washed with Na₂SO₃ (10% aq, 2×100 mL), HCl (5% aq, 1×100 mL), and brine (2×100 mL). The organics were removed and dried with MgSO₄, filtered, and concentrated to a dark solid, which was purified by column chromatography (SiO₂ gel, CHCl₃ eluent) to afford dyad 3 as a pure red-orange solid (254 mg, 5%). ¹H NMR (CDCl₃): δ 7.51 (s, 4H, phenylene Ar—H), 2.55 (s, 12H, —CH₃), 2.32 (q, 8H, —CH₂), 1.47 (s, 12H), 1.00 (t, 12H).

### Example 2

### General Reaction Scheme for Directly Linked Dyads 4, 5, 6, and 7 of FIG. 3

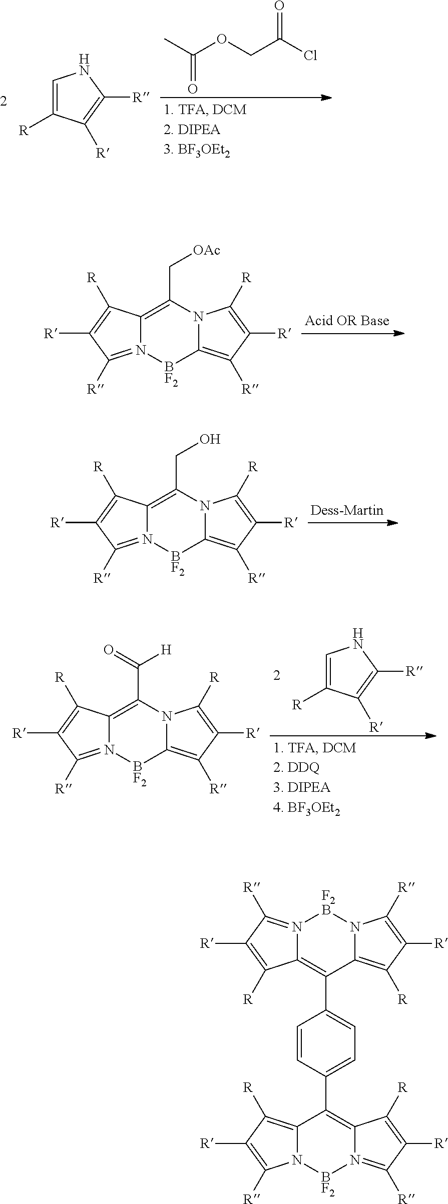

Directly Linked Dyad 4.

2-Methylpyrrole (2.01 g, 24.8 mmol) was dissolved in dry, degassed CH₂Cl₂ (20 mL) in an oven-dried three-necked flask that had been purged with N₂. The solution was cooled to 0° C. and acetoxyacetyl chloride (2.02 g, 14.8 mmol) was added in one portion in the dark and the reaction was allowed to proceed with stirring for 1 h, during which time the color turned dark red. N,N-Diisopropylethylamine (8.58 mL, 49.3 mmol) was added at room temperature, causing a color change to clear orange, and stirring was continued for 30 min followed by dropwise addition of BF₃.OEt₂ (6.18 mL, 49.3 mmol). During addition of BF₃.OEt₂ the color changed to dark red. The reaction was left stirring for 30 min and then was concentrated and purified by flash chromatography (SiO₂ gel, 25% CH₂Cl₂/hexanes, R_{f}=0.14) to yield 8-acetoxymethyl-4,4-difluoro-3,5-dimethyl-4-boro-3a,4a-diaza-s-indacene as a gold-pink solid (235 mg, 11%). ¹H NMR (CDCl₃, 600 MHz): δ 7.18 (d, ³J_{HH}=4.2 Hz, 2H, BODIPY Ar—H), 6.30 (d, ³J_{HH}=4.2 Hz, 2H, BODIPY Ar—H), 5.22 (s, 2H, —CH₂), 2.62 (s, 6H, —CH₃), 2.09 (s, 3H, —COCH₃). ¹³C NMR (CDCl₃, 600 MHz): δ 170.20, 158.96, 134.60, 133.97, 127.98, 119.84, 59.11, 20.85, 14.98. HRMS for C₁₄H₁₆BN₂O₂F₂ (MH+) calcd 293.1267. found 293.1261. 8-Acetoxymethyl-4,4-difluoro-3,5-dimethyl-4-boro-3a,4a-diaza-s-indacene (350 mg, 1.20 mmol) was dissolved in acetone (60 mL) and a solution of 4 M HCl (36 mL) was added. A condenser was fitted to the flask and the reaction was heated to 40° C. until the solution turned green and the TLC showed no starting material. The crude mixture was diluted with CH₂Cl₂, washed with water (2×75 mL), saturated NaHCO₃ (2×75 mL) and the organic layer was removed, dried over MgSO₄, filtered, concentrated and purified by flash chromatography (SiO₂ gel, CH₂Cl₂, R_{f}=0.16) to afford 8-hydroxymethyl-4,4-difluoro-3,5-dimethyl-4-boro-3a,4a-diaza-s-indacene as a red-gold solid (210 mg, 71%). ¹H NMR (CDCl₃, 600 MHz): δ 7.23 (d, ³J_{HH}=4.2 Hz, 2H, BODIPY Ar—H), 6.97 (s, 1H, —OH), 6.27 (d, ³J_{HH}=4.2 Hz, 2H, BODIPY Ar—H), 4.79 (s, 2H, —CH₂), 2.60 (s, 6H, —CH₃). ¹³C NMR (CDCl₃, 600 MHz) δ 158.41, 139.17, 133.97, 127.59, 119.53, 59.45, 14.93. HRMS for C₁₂H₁₄BN₂OF₂ (MH+) calcd 251.1162. found 251.1167. 8-hydroxymethyl-4,4-difluoro-3,5-dimethyl-4-boro-3a,4a-diaza-s-indacene (200 mg, 0.8 mmol) was dissolved in dry, degassed CH₂Cl₂ (15 mL) and was cannulated into a solution of Dess-Martin periodinane (509 mg, 1.20 mmol) in dry, degassed CH₂Cl₂ (15 mL) at 0° C. The solution was allowed to warm to room temperature and left stirring for 1 h. When the TLC showed no starting material the reaction was quenched with saturated Na₂S₂O₃ (50 mL), washed with saturated NaHCO₃ (2×50 mL) and water (2×50 mL). The organic layer was removed, dried over MgSO₄, filtered and concentrated, then purified by passing through a plug of SiO₂ gel with CH₂Cl₂ (R_{f}=0.38). 8-Formylmethyl-4,4-difluoro-3,5-dimethyl-4-boro-3a,4a-diaza-s-indacene was collected as a dark purple solid (164 mg, 83%). ¹H NMR (CDCl₃, 600 MHz): δ 10.33 (s, 1H, —CHO), 7.51 (d, ³J_{HH}=4.2 Hz, 2H, BODIPY Ar—H), 6.40 (d, ³J_{HH}=4.2 Hz, 2H, BODIPY Ar—H), 2.65 (s, 6H, —CH₃). ¹³C NMR (CDCl₃, 600 MHz) δ 188.75, 161.39, 134.87, 129.74, 125.87, 121.86, 15.33. HRMS for C₁₂H₁₂BN₂OF₂ (MH+) calcd 249.1005. found 249.1008. 8-Formyl-4,4-difluoro-3,5-dimethyl-4-boro-3a,4a-diaza-s-indacene (36 mg, 0.15 mmol) was dissolved in dry, degassed CH₂Cl₂ (10 mL) and 2-methylpyrrole (24 mg, 0.29 mmol) was added. The reaction was monitored by TLC until no starting material remained. DDQ (33 mg, 0.15 mmol) was added in one portion and the reaction was monitored by TLC until the condensat0i0on product was consumed. N,N-Diisopropylethylamine (0.10 mL, 0.58 mmol) was added in one portion, followed after 15 min by dropwise addition of BF₃.OEt₂ (0.07 mL, 0.6 mmol). The reaction was left stirring for 15 min and then was quenched with saturated Na₂S₂O₃ (25 mL), washed with saturated NaHCO₃ (2×50 mL) and the organic layer was removed. The crude mixture was dried over MgSO₄, filtered and passed through a plug of SiO₂ gel using CH₂Cl₂ (R_{f}=0.33) to recover a dark pink-green solid (25 mg, 38%). UV-vis (CH₂Cl₂) λₘₐₓ: 334, 530. ¹H NMR (CDCl₃, 400 MHz): δ 6.84 (d, ³J_{HH}=4.4 Hz, 4H, BODIPY Ar—H), 6.23 (d, ³J_{HH}=4.4 Hz, 4H, BODIPY Ar—H), 2.65 (s, 12H, —CH₃). ¹³C NMR (CDCl₃, 600 MHz) δ 159.55, 135.04, 131.87, 130.06, 120.13, 15.06. HRMS for C₂₂H₂₁B₂N₄F₄ (MH+) calcd 439.1883. found 439.1893.

Directly Linked Dyad 4 (Alternate Synthetic Scheme).

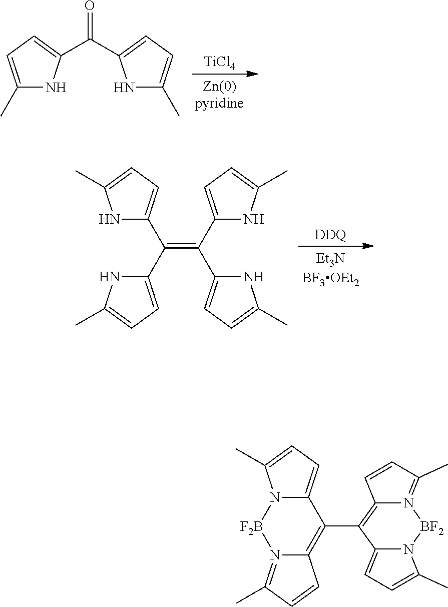

Step 1: 1,1,2,2-tetrakis(5-methyl-IH-pyrrol-2-yl)ethene. Titanium tetrachloride (87 uL, 0.80 mmol) was added dropwise to a solution of dry THF (15 mL) at 0° C. under nitrogen. The solution was stirred for 10 min, after which a suspension of zinc powder (98 mg, 1.5 mmol) in 3 mL of dry THF was added via cannula. The resulting blue slurry was heated at reflux for 3 h and cooled to room temperature. Dry pyridine (55 uL, 0.68 mmol) was added and the solution set to reflux for 30 min. After cooling to room temperature, bis(5-methyl-1H-pyrrol-2-yl)methanone in 3 mL of dry THF was added via cannula, and the solution refluxed for 3 h. The reaction was cooled to room temperature and poured into 100 mL of K₂CO₃ solution (10% aq), which was then stirred vigorously for 10 min. Organics were removed by extraction into dichloromethane, and washed with water (2×50 mL) and brine (1×50 mL), and dried over MgSO₄. Solvent was removed, and the crude product used without further purification. MALDI, m/z for C₂₂H₂₄N₄ calcd 344.20. found 344.41.

Step 2: Bis(4,4-ditluoro-3,5-dimethyl-4-bora-3a,4a-diaza-s-indacene-8-yl). 1,1,2,2-tetrakis(5-methyl-1H-pyrrol-2-yl)ethene (90 mg, 0.26 mmol) was dissolved in dry, degassed CH₂Cl₂ (15 mL) under N₂. The solution was degassed for an additional 5 min, and Et₃N (0.29 mL, 2.0 mmol) added by syringe. The resulting solution was stirred for 30 min at room temperature and DDQ (68 mg, 0.30 mmol) added. The solution was allowed to stir for an additional 30 min, after which boron trifluoride diethyl etherate (0.331 mL, 2.62 mmol) was added slowly. After 2 h, the mixture was quenched with saturated NaHCO₃ and stirred overnight. The organics were removed and washed with Na₂SO₃ (10% aq, 3×25 mL), water (2×25 mL), and brine (2×25 mL). The organics were dried over MgSO₄, filtered, and concentrated to a dark red oil, which was purified by column chromatography (SiO₂ gel, 1:1 CH₂Cl₂:hexanes, Rr=0.35) to afford 4 as a pink solid (3 mg, 3%). A small quantity of green reflective crystals was obtained by slow evaporation from a CHCl₃ solution of 4 at room temperature. These were used for photophysical analysis, but were too thin for X-ray diffraction studies. UV-vis (CH₂Cl₂) λmax: 334, 530. IH NMR (CDCl₃): δ 6.84 (d, ³J_{HH}=4.2 Hz, 4H, BODIPY Ar—H), 6.23 (d, ³J_{HH}=4.2 Hz, 4H, BODIPY Ar—H), 2.65 (s, 12H, —CH₃). MALDI, m/z for C₂₂H₂₀B₂F₄N₄ calcd 438.18 (100%), 437.18 (49%), 439.18 (25%). found 437.94 (100%), 438.96 (61%), 437.01 (45%).

Directly Linked Dyad 5.

8-Formyl-4,4-difluoro-1,3,5,7-tetramethyl-4-boro-3a,4a-diaza-s-indacene was synthesized similarly to 8-formyl-4,4-difluoro-3,5-dimethyl-4-boro-3a,4a-diaza-s-indacene. 8-Formyl-4,4-difluoro-1,3,5,7-tetramethyl-4-boro-3a,4a-diaza-s-indacene (97 mg, 0.35 mmol) was dissolved in dry, degassed CH₂Cl₂ (30 mL) and 2,4-dimethylpyrrole (70 mg, 0.74 mmol) was added. The reaction was monitored by TLC until no starting material remained. DDQ (80 mg, 0.35 mmol) was added in one portion and the reaction was monitored by TLC until the condensation product was consumed. N,N-Diisopropylethylamine (0.25 mL, 14 mmol) was added in one portion, followed after 15 min by dropwise addition of BF₃.OEt₂ (0.18 mL, 14 mmol). The reaction was left stirring for 15 min and then was quenched with saturated Na₂S₂O₃ (25 mL), washed with saturated NaHCO₃ (2×50 mL) and the organic layer was removed. The crude mixture was dried over MgSO₄, filtered and passed through a plug of SiO₂ gel using CH₂Cl₂ to recover a dark pink-green solid (25 mg, 38%). ¹H NMR (CDCl₃): δ 6.02 (s, 4H, BODIPY Ar—H), 2.56 (s, 12H, —CH₃), 1.89 (s, 12H, —CH₃).

Directly Linked Dyad 6.

8-Formyl-4,4-difluoro-1,3,5,7-tetramethyl-2,6-diethyl-4-boro-3a,4a-diaza-s-indacene was synthesized similarly to 8-formyl-4,4-difluoro-1,3,5,7-tetramethyl-4-boro-3a,4a-diaza-s-indacene. 8-Formyl-4,4-difluoro-1,3,5,7-tetramethyl-2,6-diethyl-4-boro-3a,4a-diaza-s-indacene (208 mg, 0.63 mmol) was dissolved in dry, degassed CH₂Cl₂ (20 mL) and 2,4-dimethyl-3-ethylpyrrole (154 mg, 0.91 mmol) was added. The reaction was monitored by TLC until no starting material remained. DDQ (142 mg, 0.63 mmol) was added in one portion and the reaction was monitored by TLC until the condensation product was consumed. N,N-Diisopropylethylamine (0.44 mL, 2.5 mmol) was added in one portion, followed after 15 min by dropwise addition of BF₃.OEt₂ (0.32 mL, 2.5 mmol). The reaction was left stirring for 15 min and then was quenched with saturated Na₂S₂O₃ (25 mL), washed with saturated NaHCO₃ (2×50 mL) and the organic layer was removed. The crude mixture was dried over MgSO₄, filtered and passed through a plug of SiO₂ gel using CH₂Cl₂ to recover a dark pink-green solid (42 mg, 11%). ¹H NMR (CDCl₃): 2.55 (s, 12H, —CH₃), 2.32 (q, 8H, —CH₂), 1.81 (s, 12H, —CH₃), 0.96 (t, 12H, —CH₃). MALDI, m/z for C₂₂H₂₀B₂F₄N₄ calcd 606.37 found 605.74.

Directly Linked Dyad 7.

8-Formyl-4,4-difluoro-3,5-dimethyl-4-boro-3a,4a-diaza-1,2,6,7-ethanoisoindole was synthesized similarly to 8-formyl-4,4-difluoro-1,3,5,7-tetramethyl-4-boro-3a,4a-diaza-s-indacene. 8-Formyl-4,4-difluoro-3,5-dimethyl-4-boro-3a,4a-diaza-1,2,6,7-ethanoisoindole (37 mg, 0.10 mmol) was dissolved in dry, degassed CH₂Cl₂ (10 mL) and 1-methyl-4,7-dihydro-2H-4,7-ethanoisoindole (32 mg, 0.20 mmol) was added. The reaction was monitored by TLC until no starting material remained. DDQ (22 mg, 0.10 mmol) was added in one portion and the reaction was monitored by TLC until the condensation product was consumed. N,N-Diisopropylethylamine (0.07 mL, 0.04 mmol) was added in one portion, followed after 15 min by dropwise addition of BF₃.OEt₂ (0.05 mL, 0.04 mmol). The reaction was left stirring for 15 min and then was quenched with saturated Na₂S₂O₃ (25 mL), washed with saturated NaHCO₃ (2×50 mL) and the organic layer was removed. The crude mixture was dried over MgSO₄, filtered and passed through a plug of SiO₂ gel using CH₂Cl₂ to recover a dark pink-green solid (5 mg, 0.7%). ¹H NMR (CDCl₃): δ 6.32 (m, 4H, alkene —CH), 6.01-5.91 (m, 4H, alkene —CH), 3.80 (m, 4H, bridgehead —CH), 3.59-3.48 (m, 4H, bridgehead —CH), 2.58 (multiple s, 12H, —CH₃), 1.25 (m, 16H, bridghead —CH₂).

### Example 3

### General Reaction Scheme for Triad 8 of FIG. 3

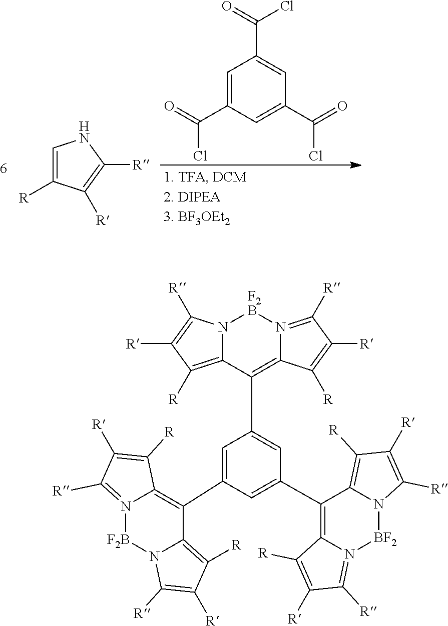

Triad 8.

1,3,5-Benzenetricarbonyl trichloride (1 g, 3.76 mmol) was dissolved in dry dichloromethane (80 ml) under N₂. 2,4-Dimethyl-3-ethylpyrrole (2.78 g, 22.6 mmol) was added and the flask was fitted with a condenser and refluxed overnight. N,N-Diisopropylethylamine (7.85 ml, 45.12 mmol) was added at reflux. After 15 minutes, the mixture was cooled to room temperature and boron trifluoride etherate (5.66 mL, 45.12 mmol) was added in one portion. After one hour, the reaction was quenched with saturated Na₂S₂O₃ (50 mL), washed with saturated NaHCO₃ (2×50 mL) and water (2×50 mL). The organic layer was removed, dried over MgSO₄, filtered and concentrated. The product was purified by flash chromatography (SiO₂ gel, CH₂Cl₂) to give the product in trace amounts. ¹H NMR (CDCl₃): δ 7.73 (s, 1H, Ar—H), 2.55 (s, 18H, BODIPY —CH₃), 2.31 (q, 12H, BODIPY —CH₂), 1.69 (s, 18H, BODIPY —CH₃), 1.01 (t, 18H, —CH₃).

### Example 4

### General Reaction Scheme for Zinc Compounds 9-12 of FIG. 3

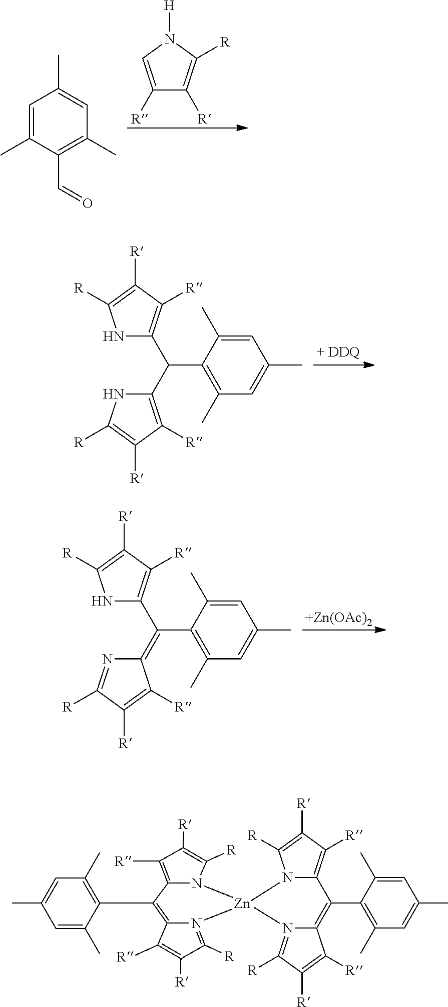

Zinc Compound 9.

5-Mesityldipyrromethane (2 g, 7.57 mmol) was dissolved in 200 ml of freshly distilled THF under Nitrogen. 2,3-Dichloro-5,6-dicyano-1,4-benzoquinone (DDQ) (1.72 g, 7.57 mmol) in 15 ml of freshly distilled THF was added slowly to the solution. Reaction mixture turned to dark red color. Reaction mixture was stirred under nitrogen for 1 hour. The reaction was quenched by adding 5 ml of Triethylamine, stirred for another 5 min. Solvent was then removed under reduced pressure. The product mixture was dissolved in 200 ml of dichloromethane, and was washed with saturated NaHCO₃ solution in water (150 ml, 3 times) and brine (150 ml, 1 time). The solution was then dried over anhydrous Na₂SO₄ and filtered. This solution of 5-mesityldipyrromethene was used without further purification. Zinc acetate dihydrate (Zn(OAc)₂.2H₂O) (10 g, 45.5 mmol) in 50 ml of methanol was added to the solution of 5-mesityldipyrromethene in dichloromethane and stirred overnight. After that, reaction mixture was filter using filter paper. Solvent was then removed under reduced pressure. The obtained solid was passed through short neutral alumina plug using hexanes/dichloromethane (50/50) mixture as eluent, the portion in orange color was collected. Solvent was then removed under reduced pressure to obtain 1 g of orange solid (14% yield). The obtained 10 was further purified by gradient sublimation under ultra high vacuum (10⁻⁵ torr) at 180° C.-140° C.-100° C. gradient temperature zones. ¹H NMR (400 MHz, CDCl₃) δ ppm 7.027.01 (m, 12H), 6.22-6.21 (m, 8H), 2.02 (s, 24H), 1.55 (s, 6H).

Zinc Compound 10.

A mixture of mesitaldehyde (4.6 g, 30.9 mmol) and 2-methylpyrrole (5 g, 61.7 mmol) was dissolved in 200 ml dichloromethane in a 500-mL single-neck round-bottomed flask was degassed with a stream of nitrogen for 10 min. Then 5 drops of trifluoroacetic acid (TFA) was added to the reaction mixture, the solution turned to dark red color. Reaction mixture was stirred under nitrogen for 6 hours until the starting materials were completely consumed. The reaction was quenched with 3 ml of triethylamine. Reaction mixture was then washed with saturated Na₂CO₃ solution in water (100 ml, 3 times) and brine (100, 1 time). Solution was dried over anhydrous Na₂SO₄. Solvent was then removed under reduced pressure to obtain the viscous pale yellow liquid (it turns to solid upon standing at room temperature). This product was dissolved in 250 ml of freshly distilled THF under Nitrogen. 2,3-Dichloro-5,6-dicyano-1,4-benzoquinone (DDQ) (7.02 g, 30.9 mmol) in 35 ml of freshly distilled THF was added slowly to the solution. Reaction mixture turned to dark red color. Reaction mixture was stirred under nitrogen for 1 hour. The reaction was quenched by adding 10 ml of triethylamine, stirred for another 5 min. Solvent was then removed under reduced pressure. The product mixture was dissolved in 500 ml of dichloromethane, and was washed with saturated NaHCO₃ solution in water (250 ml, 3 times) and brine (250 ml, 1 time). The solution was then dried over anhydrous Na₂SO₄ and filtered. Zinc acetate dihydrate (Zn(OAc)₂.2H₂O) (20 g, 91 mmol) in 100 ml of methanol was added to the solution in dichloromethane and stirred overnight. After that, reaction mixture was filter using filter paper. Solvent was then removed under reduced pressure. The obtained solid was passed through short neutral alumina plug using hexanes/dichloromethane (70/30) mixture as eluent, the portion in orange-red color was collected. Solvent was then removed under reduced pressure to obtain 2.5 g of dark green solid (12.3% total yield). The obtained 10 was further purified by gradient sublimation under ultra high vacuum (10⁻⁵ torr) at 220° C.-160° C.-120° C. gradient temperature zones. 1H NMR (400 MHz, CDCl₃): δ ppm 6.92 (s, 4H), 6.46-6.43 (m, J=4.25 Hz, 4H), 6.13 (d, J=3.94 Hz, 4H), 2.37 (s, 6H), 2.14 (s, 12H), 2.11 (s, 12H).

Zinc Compound 11.

A mixture of mesitaldehyde (5 g, 33.5 mmol) and 2,4dimethylpyrrole (6.4 g, 67 mmol) was dissolved in 250 ml dichloromethane in a 500-mL single-neck round-bottomed flask was degassed with a stream of nitrogen for 10 min. Then 5 drops of trifluoroaceticacid (TFA) was added to the reaction mixture, the solution turned to dark red color. Reaction mixture was stirred under Nitrogen for 7 hours until the starting materials were completely consumed. The reaction was quenched with 3 ml of triethylamine. Reaction mixture was then washed with saturated Na₂CO₃ solution in water (100 ml, 3 times) and brine (100, 1 time). Solution was dried over anhydrous Na₂SO₄. Solvent was then removed under reduced pressure to obtain the viscous pale yellow liquid (it turns to solid upon standing at room temperature). The crude product obtained was dissolved in 250 ml of freshly distilled THF under nitrogen. DDQ (7.61 g, 30.9 mmol) in 40 ml of freshly distilled THF was added slowly to the solution. Reaction mixture turned to dark red color. Reaction mixture was stirred under nitrogen for 1 hour. The reaction was quenched by adding 10 ml of Triethylamine, stirred for another 5 min. Solvent was then removed under reduced pressure. The product mixture was dissolved in 500 ml of dichloromethane, and was washed with saturated NaHCO₃ solution in water (250 ml, 3 times) and brine (250 ml, 1 time). The solution was then dried over anhydrous Na₂SO₄ and filtered. This solution of 1,3,1,9-tetramethyl-5-Mesityldipyrromethene was used without further purification. Zinc acetate dihydrate (Zn(OAc)₂.2H₂O) (20 g, 91 mmol) in 100 ml of methanol was added to the solution of 1,3,7,9-tetramethyl-5-Mesityldipyrromethene in dichloromethane and stirred overnight. After that, reaction mixture was filter using filter paper. Solvent was then removed under reduced pressure. The obtained solid was passed through short neutral alumina plug using hexanes/dichloromethane (70/30) mixture as eluent, the portion in orange-red color was collected. Solvent was then removed under reduced pressure to obtain 3.0 g of orangered solid (13% total yield). The obtained 11 was further purified by gradient sublimation under ultra high vacuum (10⁻⁵ torr) at 230° C.-160° C.-120° C. gradient temperature zones. ¹H NMR (500 MHz, CDCl₃): δ ppm 6.93 (s, 4H), 5.91 (s 4H), 2.35 (s, 6H), 2.12 (s, 12H), 2.04 (s, 12H), 1.31 (s, 12H). ¹³C NMR (500 MHz, CDCl₃): δ ppm 155.90, 143.63, 143.15, 137.35, 136.22, 135.57, 134.54, 128.73, 119.56, 21.21, 19.26, 16.12, 14.83. HRMS: calcd for C₄₄H₅₁N₄Zn (MH⁺): 699.3400. found: 699.3407. C, H, N elemental analysis for C₄₄H₅₁N₄Zn: calcd (%) C (75.47), H (7.20), N (8.00). found (%) C (75.84), H (7.27), N (8.06).

Zinc Compound 12.

2,8diethyl1,3,7,9-tetramethyl-5-Mesityldipyrromethane. A mixture of mesitylaldehyde (2 g, 13.4 mmol) and 3-ethyl2,4dimethylpyrrole (3.3 g, 26.8 mmol) was dissolved in 150 ml dichloromethane in a 500-mL single-neck round-bottomed flask was degassed with a stream of nitrogen for 10 min. Then 3 drops of trifluoroaceticacid (TFA) was added to the reaction mixture, the solution turned to dark red color. Reaction mixture was stirred under Nitrogen for 7 hours until the starting materials were completely consumed. The reaction was quenched with 3 ml of triethylamine. Reaction mixture was then washed with saturated Na₂CO₃ solution in water (100 ml, 3 times) and brine (100, 1 time). Solution was dried over anhydrous Na₂SO₄. Solvent was then removed under reduced pressure. This product was dissolved in 150 ml of freshly distilled THF under nitrogen. DDQ (3.3 g, 13.4 mmol) in 15 ml of freshly distilled THF was added slowly to the solution. Reaction mixture turned to dark red color. Reaction mixture was stirred under nitrogen for 1 hour. The reaction was quenched by adding 10 ml of Triethylamine, stirred for another 5 min. Solvent was then removed under reduced pressure. The product mixture was dissolved in 300 ml of dichloromethane, and was washed with saturated NaHCO₃ solution in water (150 ml, 3 times) and brine (150 ml, 1 time). The solution was then dried over anhydrous Na₂SO₄ and filtered and was used without further purification. Zinc acetate dihydrate (Zn(OAc)₂.2H₂O) (8 g, 36.4 mmol) in 50 ml of methanol was added to the solution of 2,8-diethyl-1,3,7,9-tetramethyl-5-mesityldipyrromethene in dichloromethane and stirred overnight. After that, reaction mixture was filter using filter paper. Solvent was then removed under reduced pressure. The obtained solid was passed through short neutral alumina plug using hexanes/dichloromethane (70/20) mixture as eluent, the portion in red color was collected. Solvent was then removed under reduced pressure to obtain 0.8 g of orangered solid (7.7% total yield). The obtained 12 was further purified by gradient sublimation under ultra high vacuum (10⁻⁵ torr) at 240° C.-160° C.-120° C. gradient temperature zones. ¹H NMR (500 MHz, CDCl₃): δ ppm 6.92 (s, 4H), 2.36 (s, 6H), 2.25 (q, J=7.40 Hz, 8H), 2.11 (s, 12H), 1.97 (s, 12H), 1.19 (s, 12H), 0.91 (t, J=7.49 Hz, 12H). ¹³C NMR (500 MHz, CDCl₃): δ ppm 154.68, 142.03, 137.19, 137.10, 137.03, 136.00, 134.17, 130.66, 128.55, 21.24, 19.47, 17.92, 15.25, 14.35, 11.75. HSMS: calcd for C₅₂H₆₇N₄Zn (MH⁺) 811.4652. found 811.4658. CNH analysis for C₅₂H₆₆N₄Zn: calcd (%) C (76.87), H (8.19), N (6.90). found C (76.98), H (8.35), N (6.97).

### Example 5

### An Organic Photosensitive Optoelectronic Device Using Compound 9 of FIG. 3

OPVs using compound 9 of FIG. 3 as a donor material and fullerene C₆₀ as an acceptor material have been fabricated using vacuum deposition technique on glass coated with Indium doped Tin Oxide (ITO) substrate. The OPV device with MoO3 as hole conducting/electron blocking layer was also fabricated. The device structures and characteristics are shown in the table below and in FIG. 21. Both devices have significant photocurrents (3.06 and 3.49 mA/cm2). External Quantum Efficiency measurements (FIG. 21(c)) confirm the contribution of compound 9 to the photocurrent (up to 30% EQE at 500 nm). The MoO3 hole conducting/electron blocking layer increases the open circuit voltage (VOC) from 0.60 to 0.82 V, while the short circuit current (JSC) and the fill factor (FF) decreases slightly compared to the device without MoO3. Thus, both devices (D1 and D2) have comparable power conversion efficiency (0.9%). One of ordinary skill in the art would understand that the OPVs of Example 5 represent only one illustration of the present invention and that OPV device performance can be improved by methods known in the art.

| Device | J_{SC} (mA/cm²) | V_{OC} (V) | FF | η (%) |
|---|---|---|---|---|
| 1 | 3.06 | 0.82 | 0.35 | 0.88 |
| 2 | 3.49 | 0.60 | 0.41 | 0.86 |

Device performance characteristics under AM1.5G illumination. D1: ITO/MoO3 (8 nm)/9 (10 nm)/C60 (40 nm)/BCP (10 nm)/Al, and D2: ITO/9 (10 nm)/C60 (40 nm)/BCP (10 nm)/Al.

Specific examples of the invention are illustrated and/or described herein. However, it will be appreciated that modifications and variations of the invention are covered by the above teachings and within the purview of the appended claims without departing from the spirit and scope of the invention.

What is claimed is:

1. An organic photosensitive optoelectronic device comprising at least one higher order compound that is capable of undergoing symmetry breaking intramolecular charge transfer in a polarizing medium, wherein said compound exhibits an absorptivity of light of greater than about 10⁴ M⁻¹ cm⁻¹ at one or more visible to near infrared wavelengths ranging from 350 to 1500 nm.

2. The device of claim 1, wherein the at least one higher order compound has a luminescent lifetime of at least 1 ps.

3. The device of claim 1, wherein the at least one higher order compound has at least C₂ symmetry.

4. The device of claim 1, wherein the at least one higher order compound is chosen from dyads, triads and tetrads.

5. The device of claim 1, wherein the at least one higher ordered compound is chosen from dyads of xanthenes dyes, coumarins, acridines, phthalocyanines, subphthalocyanines, porphyrins, acenes, perylenes, malachites, cyanines, bipyridines, and dipyrrins.

6. The device of claim 1, wherein the at least one higher order compound is chosen from:

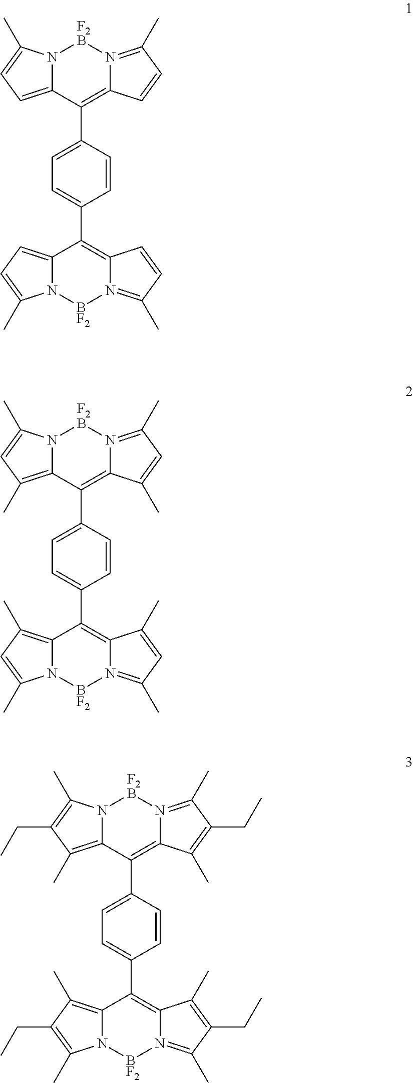

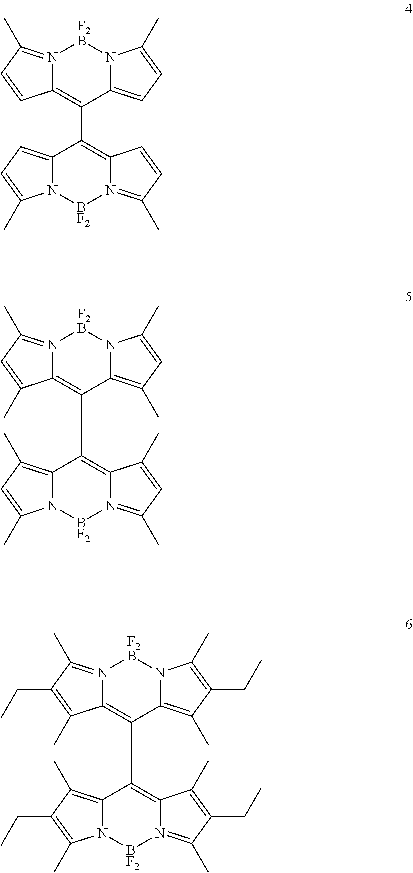

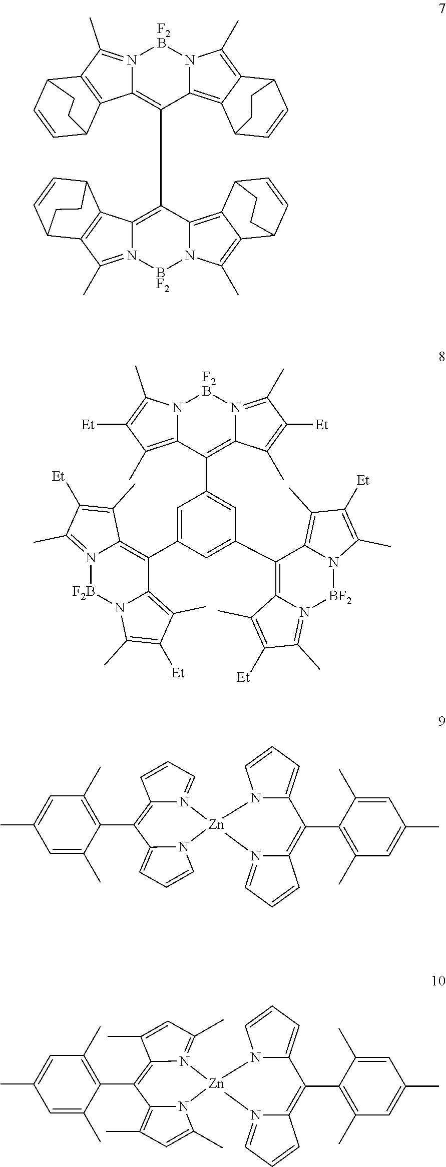

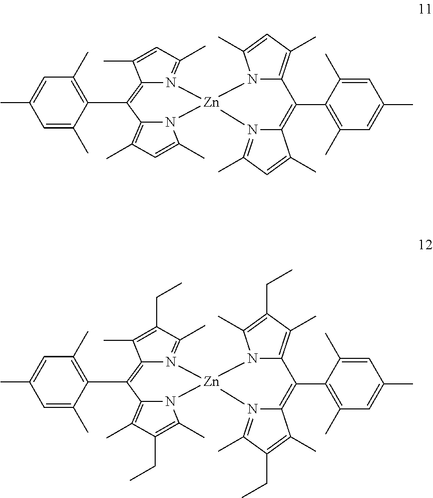

7. The device of claim 1, wherein the intramolecular charge transfer occurs at a polarizing donor/acceptor interface.

8. The device of claim 1, wherein the intramolecular charge transfer in the excited state is energetically accessible from a photogenerated S₁ state in a polarizing medium.

9. The device of claim 5, wherein the dyads may be connected either directly or through a linker, such that the dyads are arranged in linear or cofacial fashion.

10. The device of claim 9, wherein the linker is chosen from a single atom, saturated or unsaturated linear or branched hydrocarbons, and aromatic rings, or constructed from aryl, fused aryl, alkyl, alkynyl, alkenyl, a heterocycle, a diazo or organosilane moieties.

11. The device of claim 10, wherein the linker is phenylene.

12. The device of claim 1, wherein the at least one higher order compound is chosen from 1,4-Bis(4,4-difluoro-3,5-dimethyl-4-bora-3a,4a-diaza-s-indacene-8-yl)benzene, a salt thereof, a hydrate thereof, Bis(4,4-difluoro-3,5-dimethyl-4-bora-3a,4a-diaza-s-indacene-8-yl), a salt thereof, or a hydrate thereof.

13. The device of claim 1, wherein the at least one higher order compound forms at least one donor and/or acceptor region in a donor-acceptor heterojunction.

14. The device of claim 10, wherein the donor-acceptor heterojunction absorbs photons to form excitons.

15. The device of claim 1, wherein the device is chosen from an organic photodetector, an organic solar cell, or an organic laser.
